(19) United States
(12) Patent Application Publication
(10) Pub. No.: US 2026/0229833 A1
(43) Pub. Date: Aug. 6, 2026

(54) DIGITAL CONTROL OF LASERS AND ASSOCIATED SYSTEMS, METHODS, AND DEVICES

(71) Applicant: AEYE, Inc., Pleasanton, CA (US)

(72) Inventors: George Wilbur Harvey, Gerlach, NV (US); Yimin Hua, Milpitas, CA (US)

(73) Assignee: AEYE, Inc., Pleasanton, CA (US)

(21) Appl. No.: 19/464,549

(22) Filed: Jan. 29, 2026

Related U.S. Application Data
(60) Provisional application No. 63/751,140, filed on Jan. 29, 2025.

(51) Int. Cl. H01S 3/0941; G01S 7/481; G01S 7/484; G01S 17/931; H01S 3/10; H01S 3/13

(52) U.S. Cl. CPC H01S 3/0941; G01S 7/4817; G01S 7/484; H01S 3/1001; H01S 3/1305; G01S 17/931

(57) ABSTRACT

An example system includes a laser source that includes a pump laser including multiple first laser diodes configured to generate optical energy, a current source, and multiple first switches, a first switch in series with a first laser diode and configured to receive a pump drive signal and control activation of the first laser diode based on the pump drive signal. The laser source further includes a seed laser including a second laser diode configured generate an optical beam and a second switch configured to receive a seed drive signal and to control current flow through the second laser diode based on the seed drive signal, and an optical amplifier configured to receive the optical beam and the optical energy and to generate a laser pulse. The example system further includes a system controller configured to generate the pump drive signal and the seed drive signal.

### CROSS-REFERENCE TO RELATED APPLICATION

The present application claims priority to and the benefit of U.S. Provisional Patent Application No. 63/751,140, filed on Jan. 29, 2025, and entitled “Systems and Methods for Laser Control,” which is incorporated by reference herein in its entirety.

### TECHNICAL FIELD

The present disclosure relates in general to digitally controlling lasers, and more particularly, to digitally controlling lasers that are used in light detection and ranging (LiDAR) systems.

### BACKGROUND

Conventional laser boards, often used for generating laser pulses in LiDAR systems, suffer from a number of shortcomings. For example, conventional laser boards provide only limited control over the characteristics of generated laser pulses. As a result, such conventional laser boards do not permit shot-to-shot variations in pulse characteristics. Further still, conventional laser boards do not provide for granular control over the shape of the generated pulses. Instead, with a conventional laser board, a trigger signal is provided to the laser board, and circuitry within the laser board may permit rudimentary control over pulse width and pulse repetition frequency via the trigger signal. To the extent that conventional laser boards permit the trigger signal to also define a pulse amplitude, this pulse amplitude cannot be controlled shot-to-shot because the conventional laser board may fire shots too quickly to enable changes to the output pulse prior to firing. For example, there is typically a delay (e.g., of at least 10-15 nanoseconds) within the laser circuitry for the trigger signal to cause any changes in the output pulse. As a result, if the pulse repetition rate of the conventional laser is around 67 MHz to 100 MHz or higher, the conventional laser cannot have its pulse characteristics controlled on a per shot basis.

Furthermore, in a conventional laser board, where the laser control electronics are housed on the same circuit board as the fiber amplifier, the laser control electronics include electronics for generating a seed laser and a pump laser. The seed laser and pump laser are fed to a fiber amplifier, which amplifies the seed laser using the pump laser to generate a laser pulse for output. This conventional laser design will often suffer from overheating problems, particularly when the board needs to be positioned in a location that may experience high temperatures. For example, conventional electronics for generating the pump laser are usually the most unreliable part of the laser system, with pump failure being a common problem.

### SUMMARY

An example system comprising a laser source including a pump laser including multiple first laser diodes configured to generate optical energy, a current source coupled to the multiple first laser diodes, and multiple first switches, a first switch of the multiple first switches coupled in series with a first laser diode of the multiple first laser diodes, wherein the first switch is configured to receive a pump drive signal of multiple pump drive signals and control activation of a corresponding first laser diode based on the pump drive signal, a seed laser including, a second laser diode configured to generate an optical beam, and a second switch configured to receive a seed drive signal and to control current flow through the second laser diode based on the seed drive signal to control a pulse amplitude of the optical beam, and an optical amplifier configured to receive the optical beam and the optical energy and to generate a laser pulse based on the optical beam and the optical energy, and a system controller configured to generate the pump drive signal and the seed drive signal.

In one example system, the laser source further includes feedback circuitry, the feedback circuitry including a photodiode configured to receive energy from the laser pulse and output current, and conversion circuitry configured to convert the current into a voltage signal, wherein the system controller is further configured to determine an energy of the laser pulse based on the voltage signal. In some embodiments, the conversion circuitry includes a capacitor configured to charge based on the current, and an amplifier configured to read a value of a voltage of the capacitor and output the voltage signal. In various embodiments, the feedback circuitry further includes gain selection circuitry configured to define a dynamic range for the current based on a gain select control signal. In one example system further comprising a scanner block configured to transmit the laser pulse, and a receiver configured to receive a returned laser pulse.

In some embodiments, the current source includes a constant current source. In one example, the multiple first laser diodes include only two first laser diodes, and wherein the system controller is configured to generate two pump drive signals to operate the two first laser diodes at duty cycles of less than 100%. In various embodiments, the first switch of the multiple first switches is coupled between the first laser diode of the multiple first laser diodes and the current source. In one example, the first switch of the multiple first switches is coupled between the first laser diode of the multiple first laser diodes and a reference potential. In one example, the pump laser further includes multiple resistive elements, a first resistive element of the multiple resistive elements coupled between the first switch of the multiple first switches and the reference potential.

An example system comprising a pump laser including multiple first laser diodes configured to generate optical energy, a current source coupled to the multiple first laser diodes, and multiple first switches, a first switch of the multiple first switches coupled in series with a first laser diode of the multiple first laser diodes, wherein the first switch is configured to receive a pump drive signal of multiple pump drive signals and control activation of a corresponding first laser diode based on the pump drive signal, a seed laser including, a second laser diode configured generate an optical beam, and a second switch configured to receive a seed drive signal and to control current flow through the second laser diode based on the seed drive signal to control a pulse amplitude of the optical beam, and an optical amplifier configured to receive the optical beam and the optical energy and to generate a laser pulse based on the optical beam and the optical energy.

One example system further comprising feedback circuitry, the feedback circuitry including a photodiode configured to receive energy from the laser pulse and output current, and conversion circuitry configured to convert the current into a voltage signal usable to determine an energy of the laser pulse. In one example system, the conversion circuitry includes a capacitor configured to charge based on the current, and an amplifier configured to read a value of a voltage of the capacitor and output the voltage signal. In some embodiments, the feedback circuitry further includes gain selection circuitry configured to define a dynamic range for the current based on a gain select control signal. In one example, the current source includes a constant current source. In another example system, the multiple first laser diodes include only two first laser diodes configured to operate at duty cycles of less than 100%. In various embodiments, the first switch of the multiple first switches is coupled between the first laser diode of the multiple first laser diodes and the current source. In one example, the first switch of the multiple first switches is coupled between the first laser diode of the multiple first laser diodes and a reference potential. In one example, the pump laser further includes multiple resistive elements, a first resistive element of the multiple resistive elements coupled between the first switch of the multiple first switches and the reference potential.

An example method comprising receiving, at pump laser circuitry that includes multiple first laser diodes, a current source, and multiple first switches, multiple pump drive signals, controlling, utilizing the multiple first switches and based on the multiple pump drive signals, activation of one or more first laser diodes of the multiple first laser diodes, generating, utilizing the one or more first laser diodes, optical energy, receiving, at seed laser circuitry that includes a second laser diode and a second switch, a seed drive signal, based on the seed drive signal, utilizing the second switch to control current flow through the second laser diode, generate, utilizing the second laser diode, an optical beam, wherein a pulse amplitude of the optical beam is determined by the current flow through the second laser diode, and generate, based on the optical beam and the optical energy, a laser pulse.

### BRIEF DESCRIPTION OF THE DRAWINGS

FIG. 1 shows an example LiDAR system according to some embodiments.

FIG. 2 depicts a system controller and a laser source of an example LiDAR system according to some embodiments.

FIG. 3A shows example seed laser circuitry for generating optical beams in response to seed drive signals in some embodiments.

FIG. 3B shows example seed laser circuitry for generating optical beams in response to digital seed drive signals in some embodiments.

FIG. 4A shows example pump laser circuitry for generating optical energy in response to digital pump drive signals in some embodiments.

FIG. 4B shows other example pump laser circuitry for generating optical energy in response to digital pump drive signals in some embodiments.

FIG. 5 shows example feedback circuitry according to some embodiments.

FIG. 6 depicts sequencing for feedback according to some embodiments.

FIGS. 7A and 7B depicts results of simulations of feedback according to some embodiments.

FIGS. 8A-8C are flow diagrams depicting example methods according to some embodiments.

FIG. 9 depicts aspects of a system controller and a laser source of an example LiDAR system according to some embodiments.

FIG. 10 depicts a block diagram of an example laser system according to some embodiments.

FIG. 11 depicts a block diagram of an example laser controller according to some embodiments.

FIG. 12A shows an example process flow for controlling the generation of seed laser signals in some embodiments.

FIG. 12B shows other example seed laser circuitry for generating seed laser signals in response to seed drive signals in some embodiments.

FIG. 13 shows other example seed laser circuitry for generating seed laser signals in response to digital seed drive signals in some embodiments.

FIG. 14A shows an example process flow for controlling the generation of pump laser signals in some embodiments.

FIG. 14B shows example pump laser circuitry for generating pump laser signals in response to pump drive signals in some embodiments.

FIG. 15A shows an example process flow for generating information indicative of a shot energy for a laser pulse based on feedback light from the laser pulse in some embodiments.

FIG. 15B shows example feedback circuitry for translating feedback light from a laser pulse into a voltage signal indicative of a shot energy for the laser pulse in some embodiments.

FIG. 15C shows an example process flow for generating information indicative of a shot energy and shot timing for a laser pulse based on feedback light from the laser pulse in some embodiments.

FIG. 15D shows another example feedback circuitry for translating feedback light from a laser pulse into voltage signals indicative of a shot energy according to some embodiments.

FIG. 16 shows another example of a distributed laser system, where the laser controller is physically separated from a fiber amplifier via optical couplings, and where the laser controller is digitally controlled by the system controller in some embodiments.

FIG. 17 shows an example LiDAR system that employs the laser system of any of the foregoing examples in some embodiments.

Throughout the drawings, like reference numerals may be understood to refer to like parts, components, and structures.

### DETAILED DESCRIPTION

Various embodiments described include a laser source that is digitally controlled by a system controller. The laser source may receive digital control signals from the system controller and utilize the digital control signals to cause a seed laser to generate an optical beam and a pump laser to generate optical energy, both of which are transmitted to an optical amplifier that utilizes the optical energy to amplify the optical beam and generate laser pulses. One or more characteristics of the laser pulses may be defined by the digital control signals. By using this example system, through digital control signals, laser pulses may be controlled on an individual basis.

In some embodiments, digital control over the laser pulses may be exercised on a per clock cycle basis so that the bits of the digital control signals may vary on each clock cycle so that the laser pulse characteristics may also vary on a per clock cycle basis as a function of the digital control signals. This mode of digital control over the characteristics of the output laser pulses) may be referred to herein as “direct digital control” (or similar variations such “direct control” or “directly controlled” in the context of digital control signals). Accordingly, the digital control signals may be or include sequences of bits whose varying bit values may directly control how one or more characteristics of the optical beam of the seed laser and/or the optical energy of the pump laser vary over time. For examples where the bit rate of the digital control signals is a rate in a first range, the clock rate of the laser controller may operate in a second range while still providing a shot rate for the laser system (e.g., X pulses per second) and achieving granular shot-by-shot control over pulse characteristics on a per clock cycle basis.

This direct digital control stands in contrast to conventional laser control systems as discussed above where such granular control of pulse characteristics is not possible. In some embodiments, the digital control signals include at least one a digital seed drive signal that controls pulse width, amplitude, and/or shape for the optical beam output by the seed laser. Further, in some embodiments, the digital control signals may include at least one digital pump drive signal that controls aspects of the optical energy generated by the pump laser.

Further, in various embodiments, a distributed laser system including the laser controller (e.g., that generates an optical beam and optical energy in response to electronic control signals) and the optical amplifier (e.g., that (1) receives the optical beam from the seed laser and the optical energy from the pump laser, (2) amplifies the received optical beam based on the received optical energy to generate an amplified laser pulse, and (3) outputs the amplified laser pulse). The distributed laser system may further include optical coupling between the laser controller and the optical amplifier. The optical coupling may propagate the optical beam and the optical energy from the laser controller to the optical amplifier. The laser controller may be physically separated from the optical amplifier via the optical coupling. The optical coupling may take the form of optical fibers for propagating the optical beam and the optical energy from the laser controller to the optical amplifier.

The physical separation between the laser controller and the optical amplifier may provide the distributed laser system with significant improvements in distributing the heat sources in the laser system. By providing for physical separation between the laser controller and the optical amplifier, users have a wide range of choices for physically positioning the laser controller relative to the optical amplifier. For example, the laser controller may be physically positioned so that it abuts or is right next to the optical amplifier. Alternately, the laser controller may be physically positioned at ranges from a few centimeters to many meters from the optical amplifier. The ability to position the laser controller away from the optical amplifier may assist to protect the optical amplifier from the heat generated by the laser controller.

Moreover, the physical separation between the laser controller and the optical amplifier also provides a user with more flexibility for reducing and/or shaping the footprint of the laser system near the laser output area. For example, a user may position the optical amplifier near the laser output area while positioning the laser controller in a different area. As a result, the size of the laser output area may be reduced and/or be shaped in a manner that may make room for other components.

It will be appreciated that the laser controller may be deployed on a laser electronics control board. The laser electronics control board may include seed laser circuitry and pump laser circuitry. The seed laser circuitry may variably control a pulse width, amplitude, and/or shape for an optical beam based on a digital seed drive signal. The pump laser circuitry may generate optical energy based on a digital pump drive signal. To interface the laser electronics control board with external components such as a system controller and an optical amplifier, the laser electronics control board may also include digital inputs, and optical outputs. For example, the electronics control board may include any number of digital inputs for receiving the digital seed drive signal and the digital pump drive signal. The optical outputs may include an optical output (e.g., a first optical output) for providing the optical beam from the laser electronics control board. The optical outputs may also include an optical output (e.g., a second optical output) for outputting the optical energy from the laser electronics control board. In some embodiments, this approach combines digital control over laser characteristics (which may take the form of direct digital control as discussed above) with the ability to position the laser electronics control board remotely from the optical amplifier. In some embodiments, the laser electronics control board may also include feedback circuitry that monitors laser pulses produced by the laser system and provides a feedback signal indicative of the energy of the laser pulses signal to a system controller for the laser electronics control board.

Seed laser circuitry may include a laser diode and variable control circuitry. The laser diode may generate an optical beam in response to a current drawn through the laser diode. The variable control circuitry may variably control an amount of current drawn through the laser diode based on a seed drive signal to control a pulse amplitude for the optical beam. The variable control circuitry may utilize any number of approaches to control the amount of current. For example, the variable control circuitry for the seed laser circuitry may take the form of a plurality of switches whose switch states are controlled by the seed drive signal to variably control the amount of current drawn through the laser diode.

In various embodiments, the seed drive signal may operate to variably control pulse width, amplitude, and/or shape for the optical beam. By variably controlling pulse width, amplitude, and/or shape for the optical beam over time, the seed laser circuitry may better support pulse coding by the laser system. Variably controlling pulse width, amplitude, and/or shape may assist, for example, to mitigate interference in scenarios where it is expected that multiple laser systems will be transmitting laser pulses over the air in the same general area. By allowing each laser system to employ its own pulse coding using granular control over the pulse width, amplitude, and/or shape for the optical beam(s), interference among the laser systems may be reduced.

In some embodiments, the seed drive signal may be digital. The digital seed drive signal may comprise a plurality of bits. The bit values may be used to variably control pulse width, amplitude, and shape for a plurality of optical beams generated by the laser diode over time. As an example, the digital seed drive signal directly controls pulse width, amplitude, and/or shape on a per clock cycle basis as noted above. In another example where the variable control circuitry comprises a plurality of switches as noted above, the seed laser circuitry may further include a plurality of resistors, and wherein the switches control which of the resistors will draw current from the laser diode based on the seed drive signal to control the pulse amplitude for the optical beam.

As another example, pump laser circuitry may include multiple laser diodes and variable control circuitry. In this example, the pump laser circuitry may include any number of laser diodes for generating optical energy. The variable control circuitry may variably control which of the multiple laser diodes will be activated based on a pump drive signal to generate the optical energy. As an example, the variable control circuitry for the pump laser circuitry may take the form of one or more switches whose switch states are controlled by the pump drive signal to variably control which of the redundant laser diodes are activated at a given time. In some embodiments, the pump drive signal may define a duty cycle for the pump laser circuitry to control pump power for the optical energy. By employing redundant laser diodes that are controllably activated to generate the optical energy, the pump laser circuitry may operate each of the redundant laser diodes at a duty cycle less than 100%, which may help extend the life the laser diodes used for generating the optical energy while also providing backup in case one of the redundant laser diodes fails. In an example where the redundant laser diodes are dual redundant laser diodes, each redundant laser diode may be operated at a duty cycle in range of 5% to 50% according to the pump drive signal so that the pump laser circuitry operates at an overall duty cycle in a range of 10% to 100%. It will be appreciated that user may choose to drive the redundant laser diodes using different duty cycle ranges than those disclosed herein.

In some embodiments, the pump drive signal is digital. In this example, the digital pump drive signal may include any number of a plurality of bits with bit values used to operate and control which of the redundant laser diodes are activated. As an example, the digital pump drive signal directly controls the activations and/or deactivations of the redundant laser diodes on a per clock cycle basis as noted above.

In various embodiments, feedback circuitry may be used to monitor laser pulses produced by a laser system. In one example, the feedback circuitry includes a photodiode and conversion circuitry for converting a photocurrent signal into a voltage signal. In one example, the photodiode may receive energy from the laser pulses and generate a photocurrent signal. The circuitry may convert the photocurrent signal into a voltage signal indicative of energy for the laser pulse. As an example, the conversion circuitry may takes the form of an amplifier (e.g., a transimpedance amplifier (TIA)) that receives a laser feedback current signal that is derived from the photocurrent signal. The TIA may convert the laser feedback current signal into the voltage signal indicative of the energy for the laser pulse.

The feedback circuitry may further comprise gain selection circuitry that defines a dynamic range for the voltage signal indicative of the laser pulse based on a gain select control signal. An input to the feedback circuitry from a system controller may provide a gain select control signal for the gain selection circuitry. The gain select control signal, for example, may vary in value as a function of an expected shot energy for the laser signal.

The feedback circuitry may further include an integrator that integrates the voltage signal over an integration time period to produce an integrated voltage signal. The integrated voltage signal may be indicative of the energy for the laser pulse. In some embodiments, the integrated voltage signal may also be indicative of a shot timing for the laser signal. The integrator may, in some embodiments, reset the integration time period based on an integrator reset control signal. In some embodiments, the system controller may provide the integrator reset control signal to the feedback circuitry so that the integration time period is reset as new laser pulses are generated by the laser system.

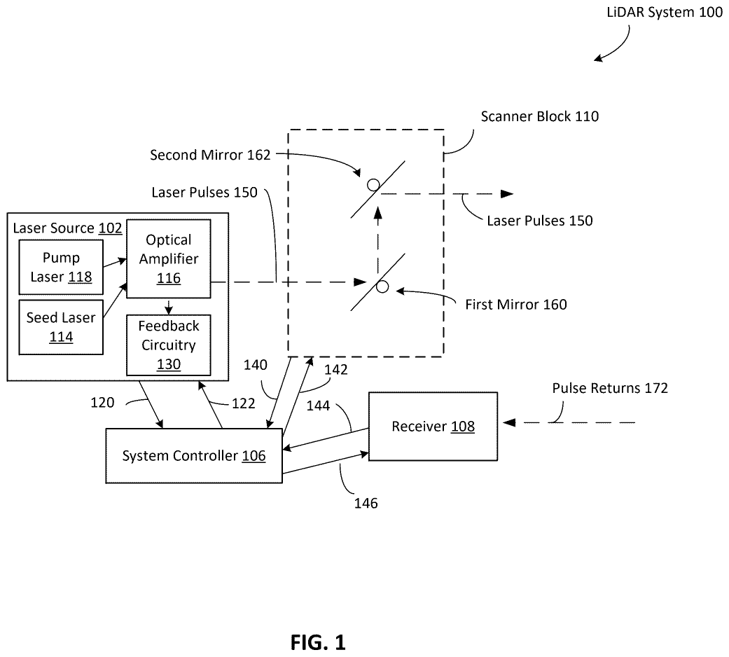

FIG. 1 shows an example LiDAR system 100 according to some embodiments. The LiDAR system 100 includes a laser source 102, a system controller 106, a receiver 108, and a scanner block 110. The laser source 102 includes a seed laser 114, a pump laser 118, an optical amplifier 116, and feedback circuitry 130. The scanner block 110 includes a first mirror 160 and a second mirror 162. The system controller 106 may send signals 122 to the laser source 102 and receive signals 120 from the laser source 102. For example, the system controller 106 may send signals 122 to the seed laser 114 to control the seed laser 114 and signals 122 to the pump laser 118 to control the pump laser 118. The laser source 102 may utilize the seed laser 114, the pump laser 118, and the optical amplifier 116 to generate laser pulses 150 that serve as LiDAR pulse shots. The laser pulses 150 output by the laser source 102 may be directed toward a target in the environment by the first mirror 160 and the second mirror 162 that are included in the scanner block 110 (or mirror subsystem) of the LiDAR system 100.

The system controller 106 may include one or more processors. The one or more processors may be implemented as any of a number of different types of compute resources, including but not limited to, one or more systems on a chip (SoCs), one or more field programmable gate arrays (FPGAs), one or more application-specific integrated circuits (ASICs), one or more digital signal processors (DSPs), one or more microprocessors (including multi-core processors), or any combinations thereof. The operations of the system controller 106 may be defined by hardware, firmware, software, and/or combinations thereof.

The system controller 106 may control not only the operations of the laser source 102, but also the operations of the scanner block 110 (via signals 142 that may control the scanning of the first mirror 160 and the second mirror 162) as well as the operations of the receiver 108 (via signals 146 that may control a variety of aspects of receiver operations). In this fashion, the system controller 106 may act as a system control circuit for the LiDAR system 100. For example, the system controller 106 may drive the first mirror 160 to scan in a resonant mode across azimuths while step scanning the second mirror 162 across elevations, where this scanning is governed by a shot list of range points in the environment to be targeted with the laser pulses 150. The shot list may not only define the order of targeting locations for the laser pulses. In one example, the shot list may also define additional characteristics of each laser pulse, including but not limited to a shot energy (pulse amplitude), pulse width, pulse shape, and/or shot time for each laser pulse. Moreover, the pulse amplitude, pulse width, and pulse shape may be defined on a per clock cycle basis for each shot. Signals 140 from the scanner block 110 may be monitored by the system controller 106 to measure the mirror scan positions for feedback control of the signals 142 to achieve desired mirror scan positions over time.

The receiver 108 may include a photodetector array that receives incident light including pulse returns 172 from the laser pulses 150. Signal processing circuitry within the receiver 108 may detect the pulse returns 172 to support the computation of range point measurements 144 for the range points that were targeted by the laser pulses 150. A LiDAR point cloud may then be populated by these range point measurements and other information derived from the pulse returns 172 to maintain a 3D map of the LiDAR system's field of view. System controller 106 may provide signals 146 to the receiver 108 to control the operations of the receiver 108, such as control signals that indicate which photodetectors of its photodetector array should be used for detecting pulse returns 172 over time and define the timing windows for such detections.

Additional disclosure as to operation of laser sources that may be generally similar to the laser source 102 and to operation of scanner blocks that may be generally similar to the scanner block 110 may be described in U.S. Pat. Nos. 10,078,133, 10,1386,467, 11,442,152, 11,474,214, 11,604,264, and 11,726,1315, the entire disclosures of which are incorporated herein by reference. Additional disclosure as to operation of receivers that may be generally similar to the receiver 108 may be described in U.S. Pat. Nos. 10,1386,467, 11,500,093, 11,604,264, 11,619,730, and 11,693,009, the entire disclosures of which are incorporated herein by reference.

While an example use with vehicles is described herein, it will be appreciated that the LiDAR system 100 or components of the LiDAR system 100 may be deployed for use cases other than vehicles, such as mining applications, forestry applications, aerial applications (e.g., aerial mapping, aerial surveillance, self-guided munitions, etc.), satellite applications, and/or the like. Moreover, it should also be understood that the vehicle use cases need not be limited to automobile use cases. In some examples, the vehicles with which the LiDAR system 100 could be used include trains, aerial vehicles, spacecraft, etc.

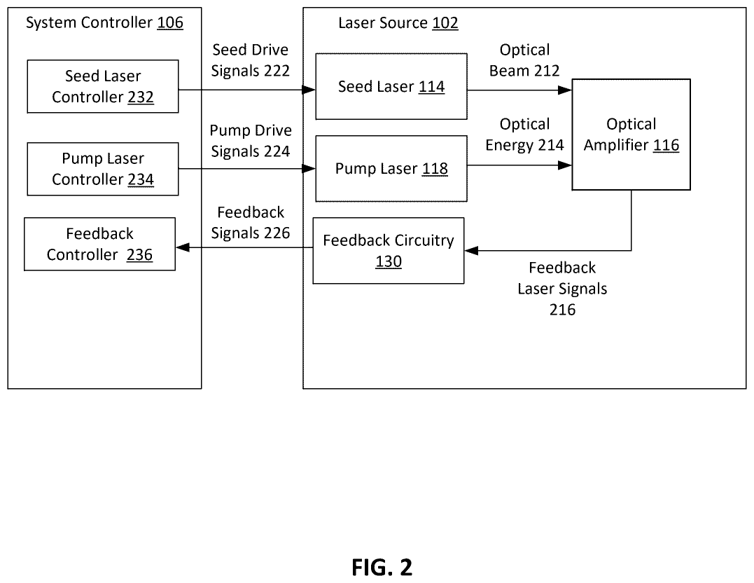

FIG. 2 depicts a block diagram of the system controller 106 according to some embodiments. The system controller 106 includes a seed laser controller 232, a pump laser controller 234, and a feedback controller 236. The seed laser controller 232 may send seed drive signals 222 to the seed laser 114 which may output an optical beam 212 (e.g., to the optical amplifier 116). The pump laser controller 234 may send pump drive signals 224 to the pump laser 118 which may output optical energy 214 (e.g., to the optical amplifier 116). The feedback circuitry 130 may receive feedback laser signals 216 and provide feedback signals 226 to the feedback controller 236. Although not depicted, the seed laser controller 232 may receive signals from the seed laser 114, the pump laser controller 234 may receive signals from the pump laser 118, and the feedback controller 236 may send signals to the feedback circuitry 130.

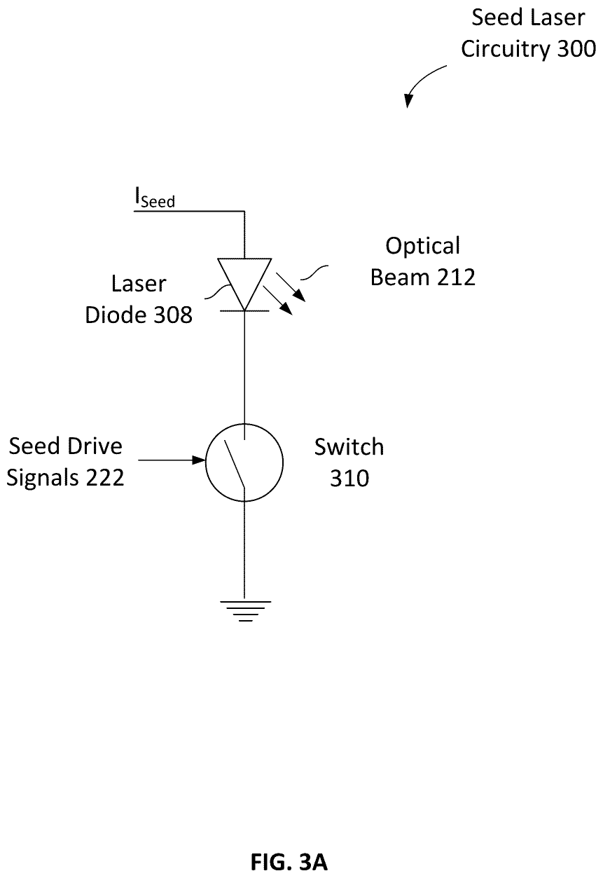

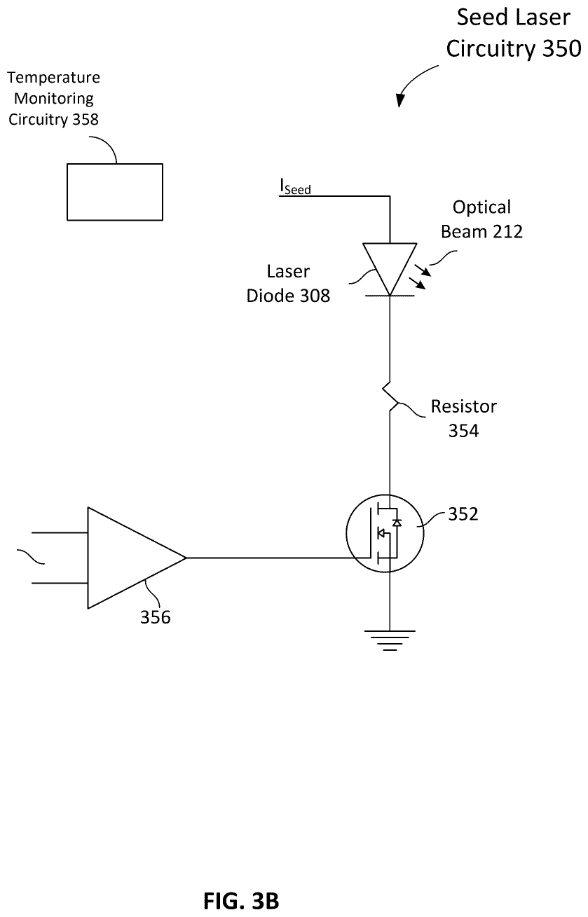

FIG. 3A shows example seed laser circuitry 300 that may be the seed laser 114, that may be included in the seed laser 114, or may interface with the seed laser 114 according to some embodiments. The seed laser circuitry 300 includes a laser diode 308 and a switch 310. The laser diode 308 may be any laser diode that is capable of producing laser pulses that exhibit the characteristics (e.g., wavelength and power characteristics) desired by a user for the optical beam 212. In the illustrated embodiment, the laser diode 308 is configured to generate a photocurrent in response to incident optical radiation.

The laser diode 308 may be driven by a bias current, I_{Seed}. The bias current allows for precise control of pulse amplitude, pulse width, and emission timing. Furthermore, driving the laser diode with a regulated current mitigates variations in forward voltage due to temperature changes, device aging, and manufacturing tolerances, thereby improving stability and reliability of the laser system.

FIG. 3B shows example seed laser circuitry 350 that may be the seed laser 114, that may be included in the seed laser 114 or may interface with the seed laser 114 according to some embodiments. This embodiment of seed laser circuitry 350 includes a single branch with a field effective transistor 352 (FET) (e.g., Gallium Nitride (GAN) FET) and a resistor 354. The field effective transistor 352 may be configured as a switch which receives as an input, the seed drive signals 222 and the resistor 354 coupled to the laser diode 308. In this example, the laser diode 308 may be driven by a bias current, I_{Seed}.

The field effective transistor 352 may be controlled by a differential amplifier 356 coupled to the field effective transistor 352. The seed drive signals 222 may be provided to the seed laser circuitry 350 as low voltage differential signaling (LVDS), providing input to the differential amplifier 356. The use of high speed GAN transistors as the switches in combination with an integrated LVDS interface for inputs may support short pulse widths. It will be appreciated that the seed drive signals 222 need not be LVDS inputs. Moreover, while FIG. 3B shows a GAN FET being used as the switch, it will be appreciated that other types of switches could be used—such as GaAs FETs, MOSFETs, etc.

The seed laser circuitry 350 may also include additional circuitry, such as temperature monitoring circuitry 358. The temperature monitoring circuitry 358 may include a temperature sensor that reports temperature information for the system controller via an I2C bus. The temperature monitoring circuitry 358 may employ an alert function to report over-temperature situations to the system controller 106.

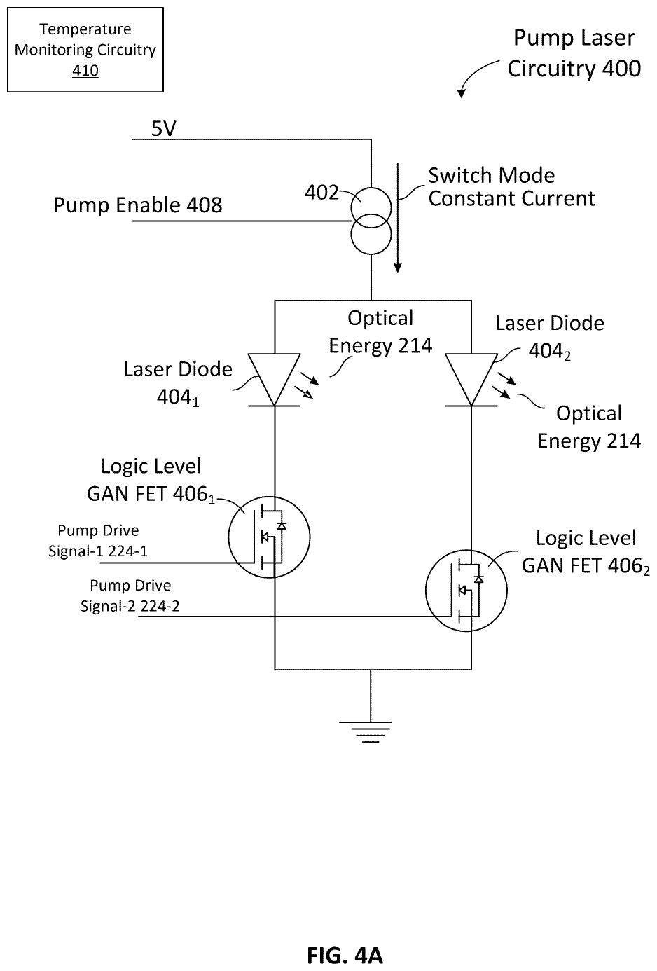

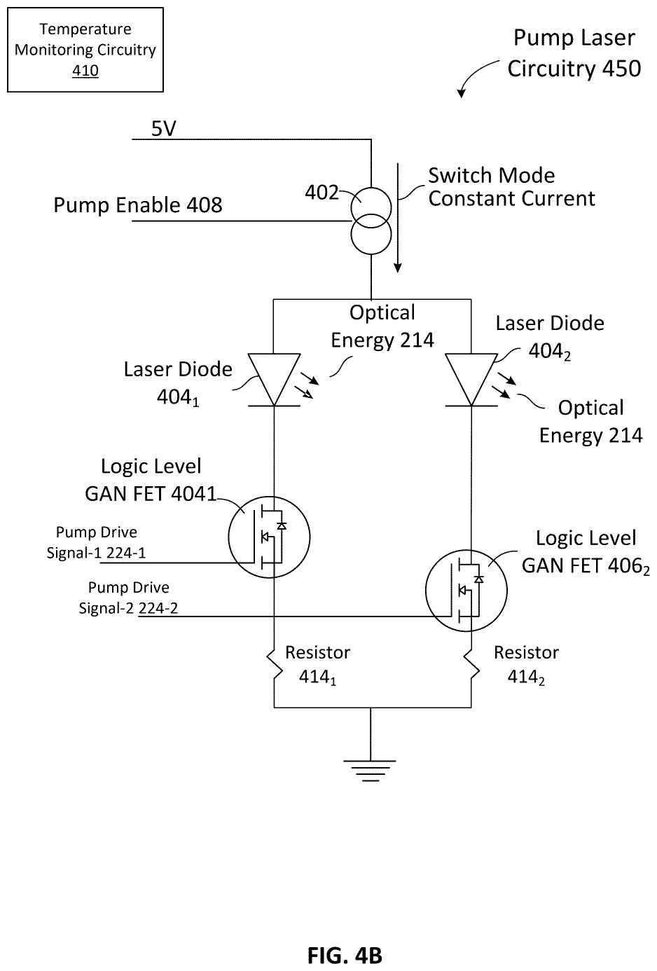

FIG. 4A shows example pump laser circuitry 400 that may be the pump laser 118, that may be included in the pump laser 118, or that may interface with the pump laser 118 in some embodiments. The pump laser circuitry 400 may generate optical energy in response to digital pump drive signals. The pump laser circuitry 400 includes dual redundant laser diodes 404₁ and 404₂, and the switches 406₁ and 406₂ take the form of two transistors such as field effect transistors (FETs) (e.g., Gallium Nitride (GAN) FETs) in some embodiments. The switches 406₁ and 406₂ (individually, collectively, switch 406) may operate at switching rates of around 500 kHz to around 1 MHz. Accordingly, the pump laser circuitry 400 in this example may be capable of varying the optical energy 214 output by the laser diodes 404 at similar rates. It will be appreciated that different types of switches could be used (e.g., GaAs FETs, MOSFETs, etc.) and different switching rates may be employed.

In the example of FIG. 4A, the current source 402 takes the form of a constant current source, such as a switching voltage regulator configured as a constant current source rather than a constant voltage source. In this example, this has the effect of providing the activated laser diodes 404₁ and 404₂ (individually, collectively, laser diode 404) with a constant current when needed. The current source 402 may provide maximum specified current to the activated laser diode.

FIG. 4A also shows an additional digital control signal, pump enable signal 408. The pump enable signal 408 may be generated by the system controller 106 that serves as a pump enable signal for the pump laser circuitry 400. For example, the pump enable signal 408 may control whether the current source 402 receives power. As such, the pump enable signal 408 may serve as a control signal for shutting down the pump laser circuitry 400 if desired.

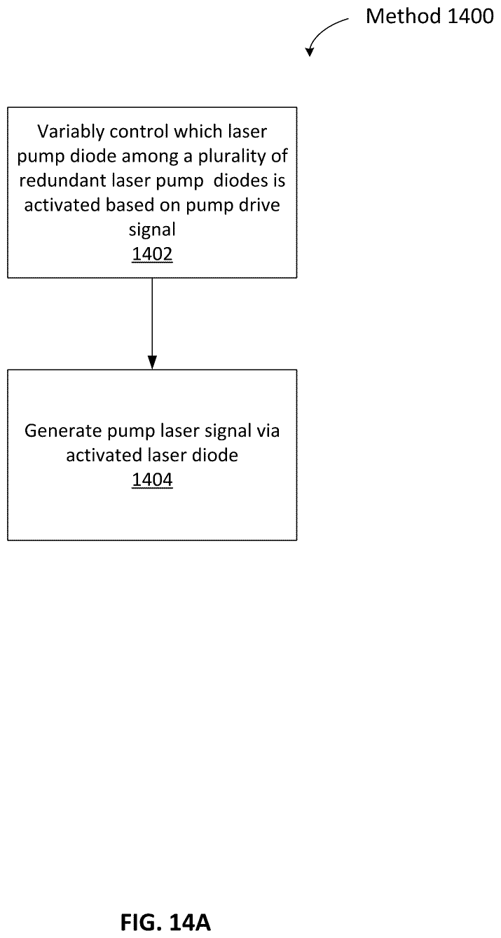

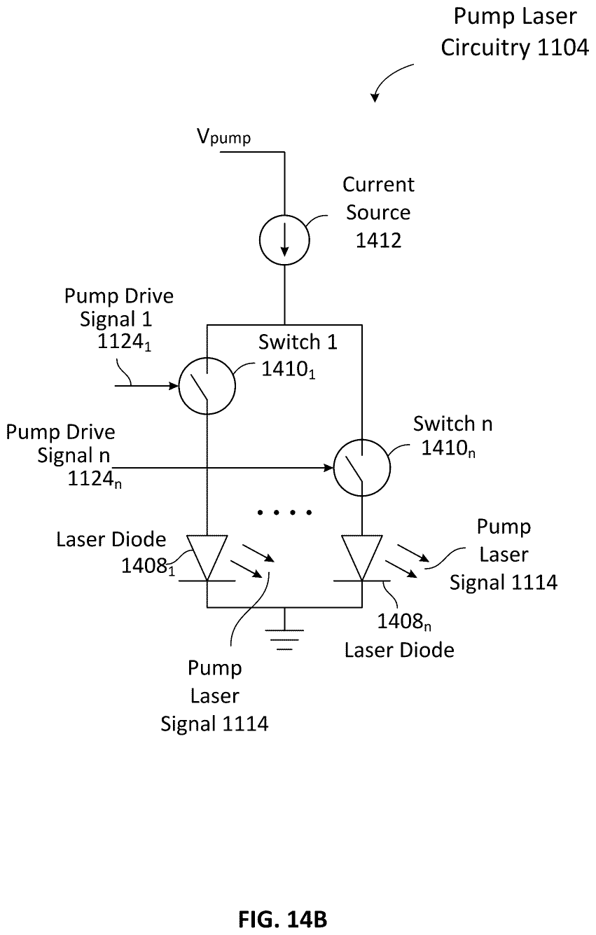

Similar to the example of FIG. 14B described herein, the pump drive signals take the form of digital pump drive signals 224-1 and 224-2, where each of the digital pump drive signals 224-1 and 224-2 is a bit value that controls the state of its corresponding switch 406 to govern whether its corresponding laser diode 404 is activated.

The pump laser circuitry 400 may also include additional circuitry, such as the temperature monitoring circuitry 410 shown in FIG. 4A. For example, the temperature monitoring circuitry 410 may include a temperature sensor that reports temperature information for the pump laser circuitry 400 to the system controller via an I2C bus. The temperature monitoring circuitry 410 may employ an alert function to report over-temperature situations to the system controller 106. In various embodiments, the temperature monitoring circuitry 410 may include or be in communication with any number of temperature sensor(s).

The illustrated embodiment of the pump laser circuitry 400 of FIG. 4A employs a low-side current control topology, as a control device, or switch 406 is coupled between the laser diode and a reference potential or ground. The switches 406 controls how much current flows to ground. The low-side driving arrangement enables high-speed modulation, simplified gate drive circuitry, accurate current sensing, and efficient handling of high pump currents in the pump laser system.

In the illustrated embodiment of the pump laser circuitry 400 of FIG. 4A, two branches, each with branch comprising the laser diode 404 coupled in series with the switch 406 between the current source 402 and ground. The dual redundant laser diodes 404₁ and 404₂, and the switches 406₁ and 406₂ reduces pump energy, while maintaining the same pump drive efficiency, duty cycles below 50% may be employed for the dual redundant laser diodes 404₁ and 404₂.

In the event one of the dual redundant laser diodes 404₁ and 404₂ fails, the surviving laser diode may be operated at a higher duty cycle (e.g., 100%) to compensate for the failure until a repair or replacement may be made. Furthermore, it will be appreciated that operating an individual laser diode continuously at a 100% duty cycle may allow for the detection of a failure in that individual laser diode 404₁ and 404₂. It can be appreciated that the pump laser circuitry 400 may include more than two redundant laser diodes.

FIG. 4B shows example pump laser circuitry 450 that may be the pump laser 118, that may be included in the pump laser 118, or that may interface with the pump laser 118 in some embodiments. The pump laser circuitry 450 is similar to the pump laser circuitry 400 of FIG. 4A, except for resistor 414ᵢ coupled between their respective switch 406ᵢ and ground. The pump laser circuitry 450 may be referred to as a low-side pump laser driver with a series sensor resistor. The resistors 414₁ and 414₂ may generate a voltage indicative of the pump laser current and may limit the magnitude of the drive current. The resistive elements 414₁ and 414₂ may be used to support closed-loop regulation of the pump laser current, to improve stability of the driver circuit, and to mitigate transient effects associated with high-speed switching. The low-side topology further enables efficient handling of high drive currents and facilitates integration of current sensing and protection functions within the pump laser system.

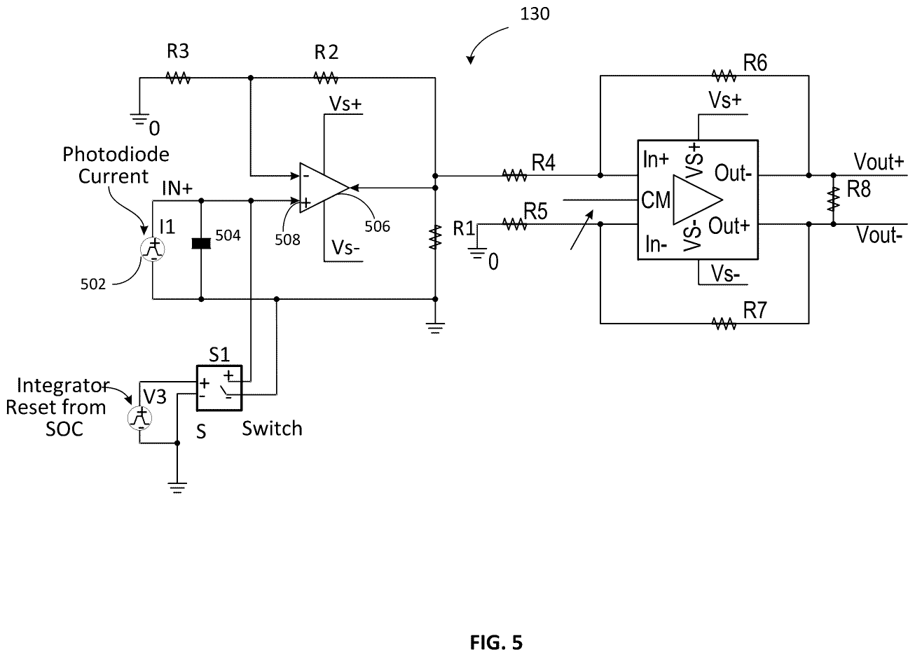

FIG. 5 shows a circuit diagram of portions of feedback circuitry 130 according to some embodiments. The feedback circuitry 130 includes a photodiode 502. In some embodiments, the photodiode 502 is a P-type Intrinsic N-type (PIN) diode.

Prior to transmitting a laser pulse, the integrator circuit is clamped to force an integration node 508 of an operational amplifier 506 to a predetermined reference potential, or ground, thereby removing residual charge stored on a capacitor 504 and establishing a known baseline condition. The capacitor and the integrator circuit may make up an integrator circuit.

After a laser pulse is generated, the photodiode 502 obtains some energy of the laser pulse that is used to charge the capacitor 504. The voltage stored in the capacitor 504 may be read by the operational amplifier 506. The output of the operational amplifier 506 may be coupled to a single-ended differential converter which converts the single-ended output of the photodiode 502 into a differential signal.

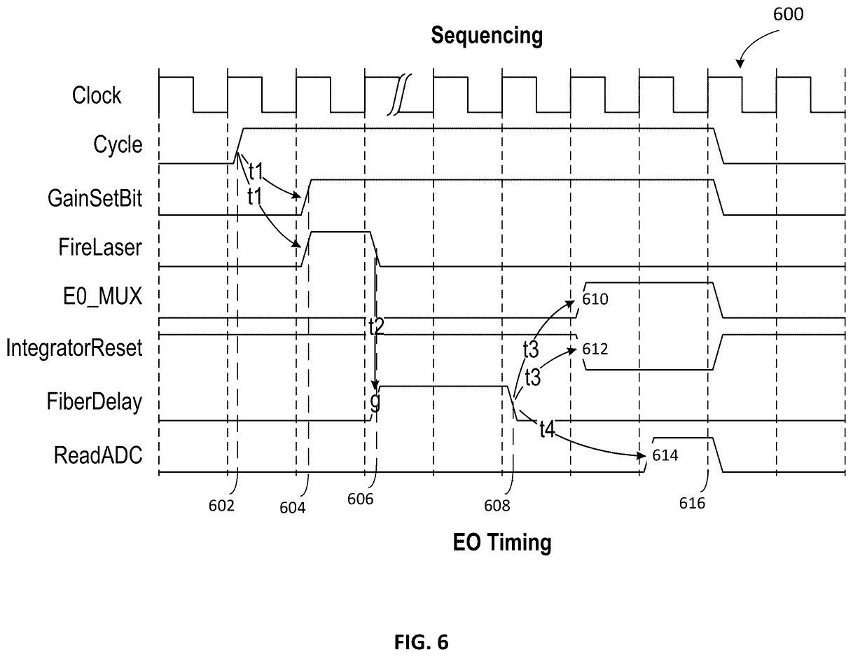

FIG. 6 shows a timing diagram 600 of the laser system according to some embodiments. The timing diagram 600 shows the change in different signals of the laser system with respect to a clock signal. At time 602, a cycle signal will be enabled which signals the beginning of a measurement cycle. The measurement cycle may refer to a time interval including emission of the pulse, reception of the reflected signal, and process of the received signal. The enabling of the cycle signal initiates the laser drive pulse and of a gain select control signal at time 602 as seen in the rising edge of the GainSetBit and FireLaser at time 604. The GainSetBit may select the integration capacitor value. In order to increase the effective pulse energy resolution, selecting a lower value of integration capacitor may result in a higher ADC reading for the same laser pulse energy. This effectively increases the ADC resolution over a range of power levels.

At time 606, the laser drive pulse is disabled, as seen in the falling edge of the FireLaser in the timing diagram 600. The fiber delay may be enabled at time 606. The fiber delay corresponds to a propagation time determined by a length and refractive index of the optical fiber, and may be configured to establish a known temporal relationship between the transmitted and received optical signals.

The end of the fiber delay, at time 608 triggers the enablement of a multiplexer, in this example, is depicted by a rising edge 610 of the E0_MUX signal. At the same time, or substantially the time as the enablement of the multiplexer, the integrator reset signal may be disabled, as seen in a falling edge 612. At this time, the switch of FIG. 5 may be opened, releasing the clamp on the operational amplifier 506 of FIG. 6, allowing the voltage stored on the capacitor 504 to amplified and converted to a digital signal. At a time period t4 after time 608, an output of the ADC may be seen may be outputting, as depicted by a rising edge at time 614. At time 616, the cycle signal and gain select control signal may be disabled, signaling the end of a particular measurement cycle, the multiplexer may be disabled, and the operational amplifier may be clamped once more, forcing an integration node 508 of the operational amplifier 506 to ground.

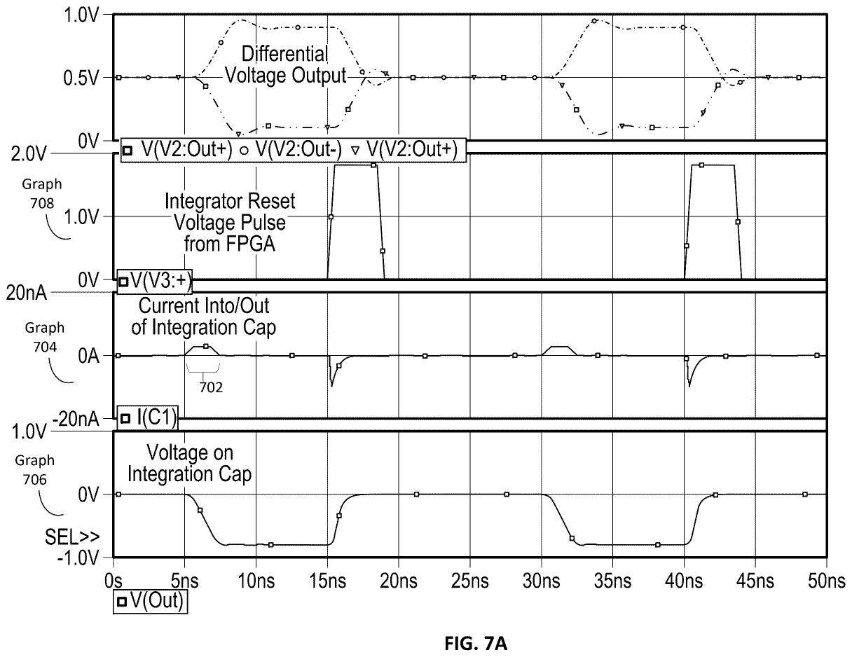

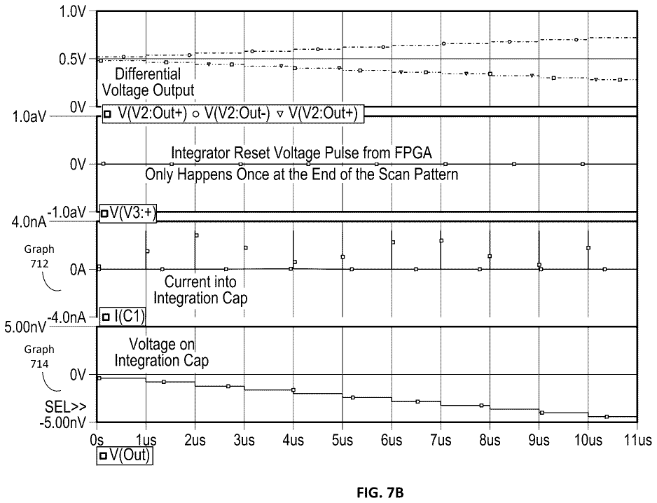

FIG. 7A depicts results of a simulation of laser pulses according to some embodiments. FIG. 7A shows voltage change in various signals of the laser system during different parts of the measurement cycle of a laser pulse energy. For example, after the transmission of the laser pulse, the laser pulse travels to the target and reflects light energy back to the receiver. The change in current of the integration capacitor seen in period 702 of graph 704 may be current output by the photodiode 502 based on energy obtained from the laser pulse. The current may be used to charge the capacitor 504. The change in the voltage on the integration capacitor, as seen in graph 706 may be an effect of the change in current of the capacitor 504. The voltage on the capacitor 504 may be reset to 0 volts with the integrator reset voltage as seen in graph 708. The capacitor 504 may be reset before transmission of the next laser pulse.

FIG. 7A shows the change in voltage and current of components of the laser system as seen in two sequential laser pulses. Over the course of a scan pattern multiple laser pulses may be required. FIG. 7B shows timing diagram of various components of the laser system over a period of time. For example, reset pulses 710 of graph 712 may be similar to the reset pulse seen in FIG. 7A. Similar to graph 708, the steady decrease in voltage on the integration capacitor in graph 714 represents multiple, laser pulses. In some embodiments, a larger size for the capacitor 504 may be utilized.

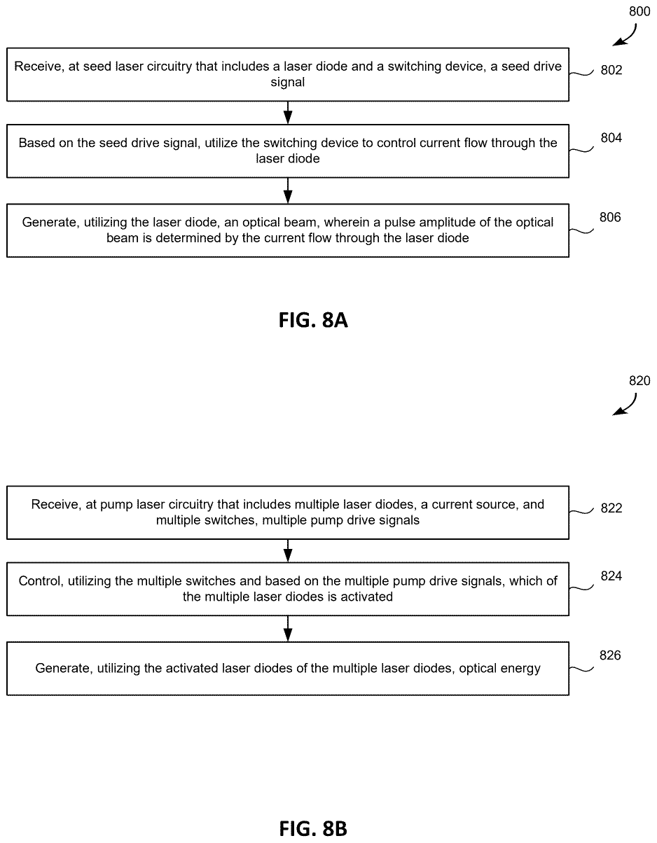

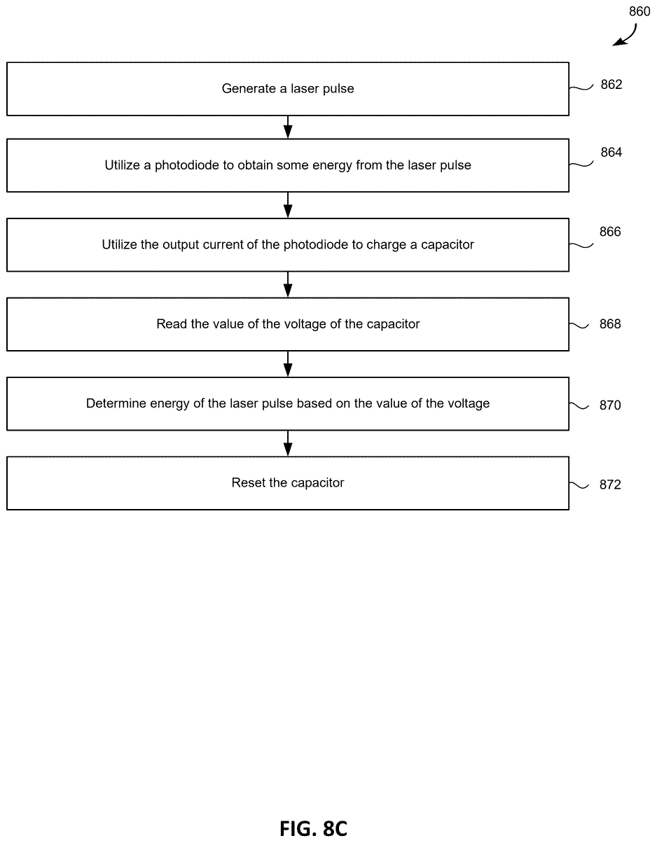

FIG. 8A is a flow diagram depicting an example method 800 for generating an optical beam according to some embodiments. The method 800 may be performed by seed laser circuitry (for example, the seed laser circuitry 300 of FIG. 3A or the seed laser circuitry 350 of FIG. 3B) alone or in combination with the system controller 106. The method 800 may begin at step 802 where, at seed laser circuitry that includes a laser diode and a switching device, a seed drive signal is received. At step 804, based on the seed drive signal, the switching device is utilized to control current flow through the laser diode. At step 806, an optical beam is generated utilizing the laser diode, where a pulse amplitude of the optical beam is determined by the current flow through the laser diode.

FIG. 8B is a flow diagram depicting an example method 820 for generating optical energy according to some embodiments. The method 820 may be performed by pump laser circuitry (for example, the pump laser circuitry 400 of FIG. 4A or the pump laser circuitry 450 of FIG. 4B) alone or in combination with the system controller 106. The method 820 may begin at step 822 where, at pump laser circuitry that includes multiple laser diodes, a current source, and multiple switches, multiple pump drive signals are received. At step 824, based on the multiple pump drive signals, the multiple switches are utilized to control which of the multiple laser diodes is activated (for example, one or more of the multiple laser diodes may be activated). At step 826, utilizing the activated laser diodes of the multiple laser diodes, optical energy is generated. For example, one or more of the multiple laser diodes may generate optical energy. The optical energy may be transmitted to an amplifier to amplify an optical beam using the optical energy.

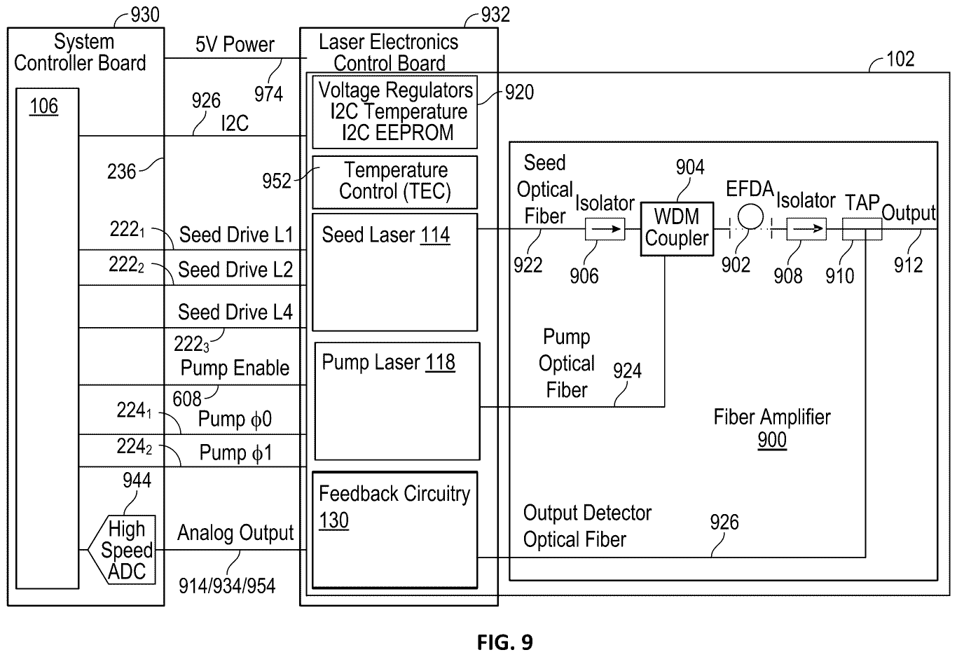

FIG. 8C is a flow diagram depicting an example method 860 for determining the energy of a laser pulse according to some embodiments. The method 860 may be performed by the feedback circuitry 130 alone or in combination with the system controller 106. The method 860 may begin at step 862 where the laser source 102 generates a laser pulse. At step 864 a photodiode (e.g., the photodiode 502 of FIG. 5) is utilized to obtain some energy from the laser pulse. At step 864 the output current of the photodiode is utilized to charge a capacitor (e.g., the capacitor 504 of FIG. 5). At step 868 the value of the voltage of the capacitor is read (e.g., by the operational amplifier 506). The value of the voltage of the capacitor may be transmitted by the feedback circuitry 130 to the system controller 106 (e.g., a high speed ADC 944 of the system controller 106, see, FIG. 9). At step 870, the energy of the laser pulse is determined based on the value of the voltage (e.g., by the system controller 106). The system controller 106 may store a value of the energy of the laser pulse, for example, in memory. The system controller 106 may then utilize the value of the energy of the laser pulse to control parameters for the seed laser 114 and/or the pump laser 118.

FIG. 9 shows a detailed view of portions of the LiDAR system 100 in accordance with an example embodiment. In this example, portions of the laser source 102 may be implemented on a laser electronics control board 932 and portions of the system controller 106 may be implemented on a system controller board 930. The optical amplifier 116 may take the form of a fiber amplifier 900. The fiber amplifier 900 may include a doped fiber amplifier such as an Erbium-doped fiber amplifier (EFDA) 902. An optical isolator 906 may be coupled to seed optical fiber 922 for receiving the optical beam 212 from the seed laser 114, and an optical coupler 904 (such as a wavelength division multiplexing (WDM) coupler) may couple the optical beam 212 received via seed optical fiber 922 with the optical energy 214 received via pump optical fiber 924 from the pump laser 118. The optical beam 212 may then be amplified within the EFDA 902 using the optical energy 214.

The amplified optical output of the EFDA 902 may be passed through optical isolator 908. In example embodiments where the laser source 102 includes feedback circuitry 130, the fiber amplifier 900 may also include an optical tap 910 that taps into the amplified optical output of the EFDA 902 passed by the optical isolator 908 to provide the feedback laser signals 216 to the feedback circuitry 130 via optical fiber 926. The amplified optical output passed as output 912 from the fiber amplifier may serve as the laser pulses 150 that are transmitted by the laser source 102. As discussed herein, the laser electronics control board 932 may include certain circuitry of the laser source 102, including the seed laser 114, the pump laser 118, and the feedback circuitry 130.

The laser source 102 may include additional components. For example, the laser source 102 may include temperature control circuitry 952 to monitor temperatures on the laser electronics control board 132. The laser source 102 may also include voltage regulators and an EEPROM and remote temperature monitoring circuitry 920 that interfaces with the system controller 106 via an I2C bus 926. The EEPROM may provide identifying information such as board identification, manufacture date, lot, rev, P/N, and the like. In some embodiments, voltage rails needed by components on the laser electronics control board 932 are generated on the laser electronics control board 932 by voltage regulators from a 5V power input 974. Furthermore, the laser source 102 may include one or more LEDs that indicate operational status information such as indications of main power, pump power, seed activity, and the like.

The laser source 102 may receive digital inputs from the system controller 106 such as the seed drive signals 222₁, 222₂, 222₃, the pump enable signal 408, and the pump drive signals 224₁, 224₂ as discussed herein. Furthermore, the laser source 102 may provide an analog electronic output to the system controller 106 in the form of voltage signals 914, 934, and/or 954. As shown by the example of FIG. 9, the system controller 106 may include a high speed ADC 944 for converting the analog output(s) 914, 934, and/or 954 into digital data. Laser control functions such as pulse repetition rate checking, temperature monitoring, and lower power monitoring may be implemented by the logic carried out by the system controller 106.

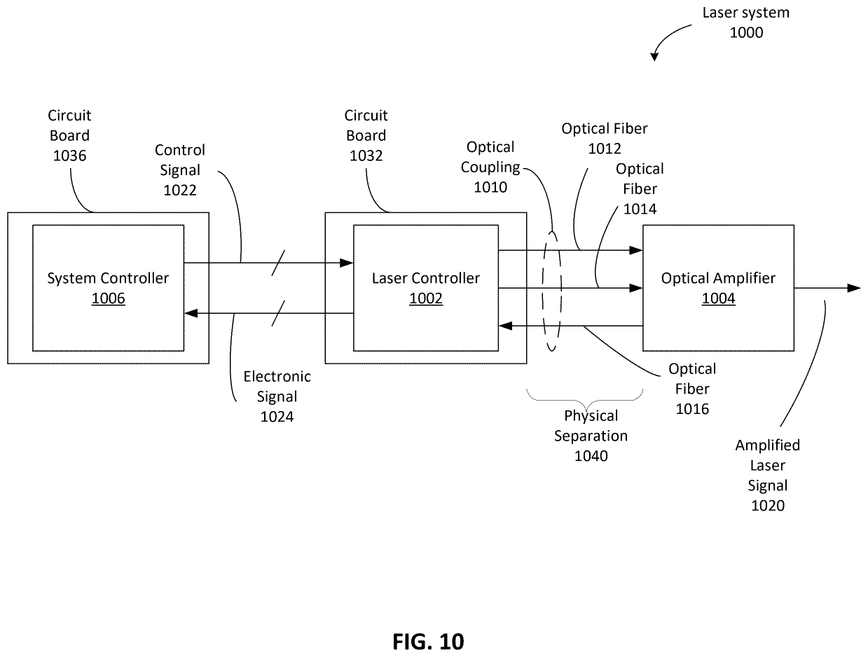

FIG. 10 shows an example of a laser system 1000 according to some embodiments. The laser system 1000 includes a laser controller 1002, an optical amplifier 1004, and a system controller 1006 in some embodiments. The laser controller 1002 may be physically separated from the optical amplifier 1004 via an optical coupling 1010. The optical coupling 1010 allows for a physical separation 1040 between the laser controller 1002 and the optical amplifier 1004. It will be appreciated that, in some embodiments, there is no separation between the laser controller 1002 and the optical amplifier 1004. In other embodiments, there may be any distance (e.g., millimeter(s), centimeter(s), or meter(s)) between the laser controller 1002 and the optical amplifier 1004. The upper constraint on the amount of physical separation 1040 may ultimately be governed only by the ability of optical carriers such as fiber optic materials to propagate light signals without undue losses. Example values for separation 1040 may include but are not limited to 5 cm, 3 inches, 6 inches, 1 foot, 2 feet, 1 meter, 10 feet, 5 meters, 50 meters, etc. (or values therebetween or longer) as may be desired by the user.

The optical coupling 1010 may include any number of optical fibers. In one example, a first optical fiber 0112 may propagate a seed laser signal from the laser controller 1002 to the optical amplifier 1004. A second optical fiber 1014 may propagate a pump laser signal from the laser controller to the optical amplifier 1004. The physical separation 1040 may be achieved by using optical fibers 1012 and 1014 of sufficient length to provide the desired physical separation 1040.

In this example, the optical amplifier 1004 amplifies the seed laser signal received via optical fiber 1012 using the pump laser signal received via optical fiber 1014 to generate an amplified laser signal 1020 for output. This amplified laser signal 1020 may serve as a laser pulse produced by the laser system 1000 for transmission (e.g., into the environment). As an example, the optical amplifier 1004 may take the form of a fiber amplifier.

The physical separation 1040 may enable a distributed laser system 1000 that better dissipates heat generated by components of the laser system 1000. In this regard, the optical amplifier 1004 may be protected from the heat generated by the electronics of the laser controller 1002 because the laser controller 1002 may be positioned remotely from the optical amplifier 1004.

In some embodiments, the physical separation 1040 provides a user with options for placing the optical amplifier 1004 in smaller locations because the location where the optical amplifier 1004 is placed need not be sized to also fit the laser controller 1002. As a result, the laser system 1000 may have a smaller footprint in the output area of the amplified laser signal 1020. For example, a user may position the optical amplifier 1004 near the laser output area while positioning the laser controller 1002 in a different area, which means the size of the laser output area may be reduced and/or be shaped in a manner that provides room for other components.

The laser controller 1002 may control generation of the seed laser signal and the pump laser signal for output via optical fibers 1012 and 1014 using control signals 1022. In various embodiments, the laser controller 1002 receives control signals 1022 from the system controller 1006. Through such control signals 1022, the system controller 1006 and/or the laser controller 1002 may control a variety of characteristics of the seed laser signal and pump laser signal as discussed below. In some embodiments, the control signals 1022 may be digital control signals that provide for highly granular digital control over characteristics of the seed laser signal and the pump laser signal, which in turn may define the characteristics of the amplified laser signal 1020. As a result, in some embodiments, the control signals 1022 may define the characteristics of the amplified laser signal 1020 on a shot-by-shot basis so that its pulse width, amplitude, and/or shape may change from shot to shot. It will be appreciated that these control signals 1022 may be clocked at high rates in a manner that supports variable control over pulse width, amplitude, and/or shape on a per clock cycle basis as noted above and below.

Furthermore, the laser controller 1002 may be deployed on a circuit board 1032, while the system controller 1006 may be deployed on a circuit board 1036. Circuit board 1032 may thus serve as a laser electronics control board for the laser system 1000. The optical amplifier 1004 may be flexibly positioned in a desired location using any suitable techniques for securing the optical amplifier 1004 in a desired location (e.g., using packaging, clamps, brackets, mounts, or the like).

The system controller 1006 may include one or more processors that control operations of the laser controller 1002 via control signals 1022. The one or more processors may be implemented as any of a number of different types of compute resources, including but not limited to, one or more systems on a chip (SoCs), one or more field programmable gate arrays (FPGAs), one or more application-specific integrated circuits (ASICs), one or more digital signal processors (DSPs), one or more microprocessors (including multi-core processors), or any combinations thereof. The system controller's operations may be defined by hardware, firmware, software, and/or combinations thereof. Through these operations, the system controller 1006 may provide suitable control signals 1022 for use in controlling the operation of the laser controller 1002.

In some embodiments, the laser controller 1002 provides feedback monitoring of the amplified laser signals 1020. For example, optical coupling 1010 may include an optical fiber 1016 that propagates a feedback laser signal (corresponding to feedback light from the amplified laser signals 1020) from the optical amplifier 1004 to the laser controller 1002. As a result, the laser controller 1002 may then generate electronic signals 1024 indicative of characteristics of the amplified laser signal 1020 (such as a shot energy and/or shot timing for the amplified laser signal 1020) to assist in system control. The system controller 1006 may receive and utilize the electronic signals 1024 to generate or alter control signals 1022.

In some embodiments, the laser system 1000 may include one or more sensors (not depicted in FIG. 2) that measure the output of the optical amplifier 1004. The sensor(s) may then send one or more measurement signal(s) to the laser controller 1002 to enable feedback. The measurement signal(s) may indicate and/or correlate to the output of the optical amplifier's pulse amplitude, shape, width, and/or the like. The laser system 1000 (e.g., via the system controller 106 and/or the laser controller 1002) may then make changes to the next or future laser emissions based in part on the feedback from the measurement signal(s).

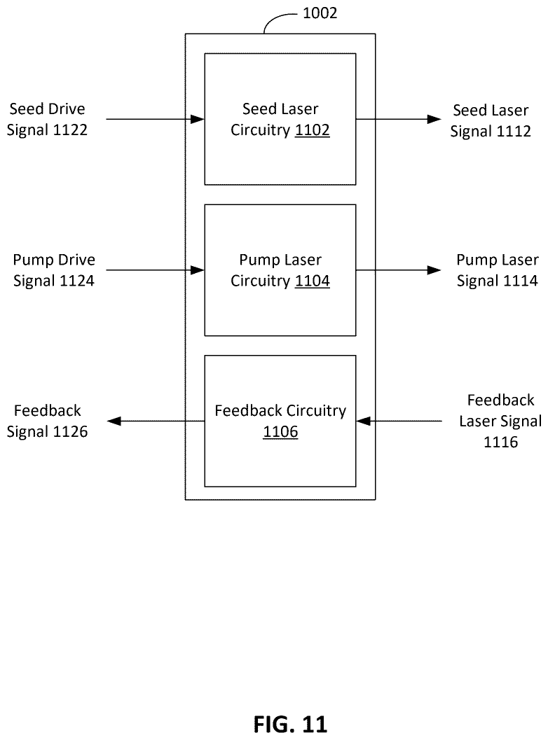

FIG. 11 shows an example laser controller 1002, where the laser controller 1002 includes seed laser circuitry 1102 and pump laser circuitry 1104 in some embodiments. In some embodiments, the seed laser circuitry 1102 may generate a seed laser signal 1112 in response to one or more seed drive signals 1122. The pump laser circuitry 1104 may generate a pump laser signal 1114 in response to one or more pump drive signals 1124.

The laser controller 1002 may provide an optical interface for communicating with the optical amplifier 1004 and an electronic interface for communicating with the system controller 1006. For example, the laser controller 1002 may include optical outputs for the seed laser signal 1112 and the pump laser signal 1114. The laser controller 1002 may include electronic inputs for the seed drive signal(s) 1222 and pump drive signal(s) 1124. In some embodiments, the optical outputs from the laser controller 1002 may be coupled to the optical fibers of the optical coupling 1010. In some embodiments, the electronic inputs to the laser controller 1002 may be linked with the system controller 1006 via electronic cables and/or connectors. The laser controller 1002 of FIG. 11 may be deployed on circuit board 1032 (see FIG. 10).

In an example where the laser controller 1002 also provides feedback monitoring of the amplified laser signal 1020, the laser controller 1002 includes feedback circuitry 1106, where the feedback circuitry 1106 receives a feedback laser signal 1116 from the optical amplifier 1004 and processes that feedback laser signal 1116 to generate one or more electronic feedback signals 1126 for output to the system controller 1006. To support the feedback circuitry 1106, the laser controller 1002 may include an input (e.g., optical input) for connection with optical fiber 1016 to receive the feedback laser signal 1116 and an electronic output for connection with the system controller 1006 via one or more cables and/or connectors to provide the feedback signal(s) 1126 to the system controller 1006.

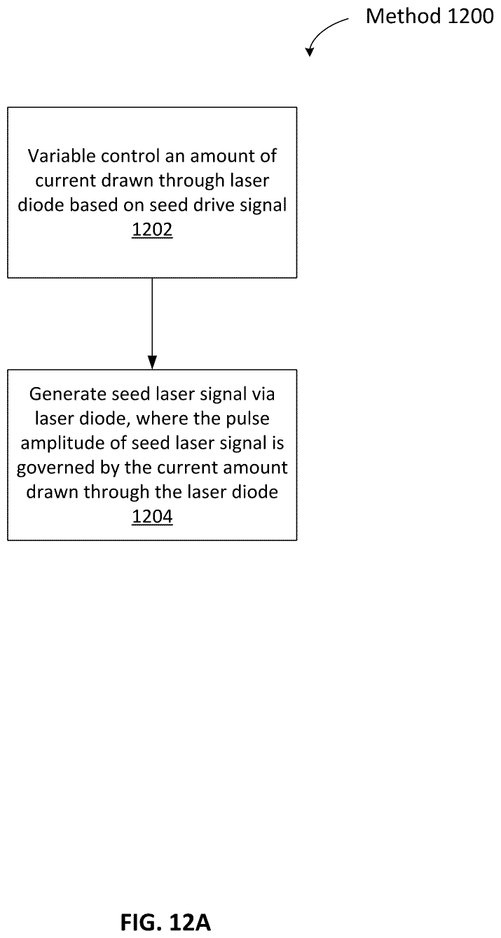

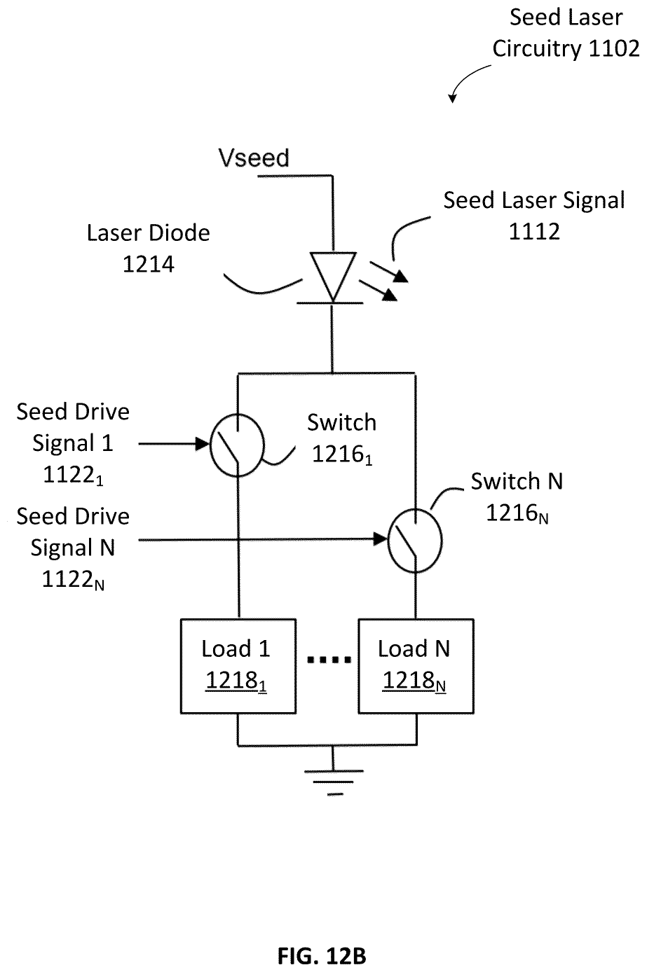

FIG. 12A shows an example method 1200 to be carried out by seed laser circuitry 1102 in some embodiments. At step 1202, the seed laser circuitry 1102 variably controls an amount of current drawn by a laser diode based on the seed drive signal(s) 1122. Step 1202 may be carried out by circuitry that operates to variably control the amount of current drawn by the laser diode as a function of the seed drive signal(s) 1122. For example, the variable control circuitry for step 1202 may comprise one or more switches whose switch states are controlled by the seed drive signal(s) 1122, where the switch states control how much current is drawn through the laser diode. It will be appreciated that other circuitry could be used for the variable control circuitry at step 1202. For example, the variable control circuitry may take the form of a current output digital-to-analog converter (DAC). In this example, the seed drive signal(s) 1122 may comprise a digital value that is converted by the current output DAC into an analog current signal that is defined by the digital value.

At step 1204, the laser diode generates the seed laser signal 1112 in a manner where the pulse amplitude of the seed laser signal 1112 is governed by the amount of current drawn through the laser diode at step 1202. Accordingly, in some embodiments, by controlling the seed drive signal(s) 1122 over time, the system controller 1006 may granularly define the pulse amplitude, shape, and width of the seed laser signal 1112. For example, pulse amplitude may be granularly controlled so that the seed laser signal 1112 exhibits any of a plurality of different non-zero pulse amplitudes. In another example, by controlling the rate of change of these different non-zero pulse amplitudes, the pulse shape of the seed laser signal 1112 may also be granularly controlled. Further, in another example, by controlling the durations of the non-zero pulse amplitudes, the pulse width of the seed laser signal 1112 may be granularly controlled.

FIG. 12B shows an example seed laser circuitry 1102 in some embodiments and includes a laser diode 1214 and a plurality of switches 12161 that control which of the loads 1218ᵢ is or are coupled to the laser diode 1214. The laser diode 1214 may be any laser diode that is capable of producing laser pulses that exhibit the characteristics (e.g., wavelength and power characteristics) desired by a user for the seed laser signals 1112.

In contrast to the example seed laser circuitry 300 of FIG. 3A, the seed laser circuitry 1102 of FIG. 12B is driven by bias voltage V_{seed}. This example of the seed laser circuitry includes multiple switches 1216ᵢ that control current through their respective current paths coupled to the laser diode 1214. The voltage-biased configuration may enable coordinated operation of multiple current modulation branches and facilitate synthesis of composite drive waveforms.

In this example, the number n of switches 1216ᵢ and loads 1218ᵢ may be any integer value greater than or equal to 2, where it will be appreciated that the upper limit for n can be any integer value that a user believes is practical and reasonable for achieving a desired amount of control of the seed laser signal 1112. In the example of FIG. 12B, each switch 1216ᵢ is connected in series with a corresponding load 1218ᵢ as a switch-load pair, and the different switch-load pairs are arranged in parallel with each other.

The seed drive signals 1122ᵢ may operate to control the state of switches 1216ᵢ to define which of the loads 12181 are coupled to the switch 1216ᵢ, which in turn variably controls the amount of current drawn through the laser diode 1214. The laser diode 1214 may be coupled to a supply voltage of V_{seed} at its anode, and, due to the parallel arrangement of loads 2118ᵢ, increasing the number of loads 1218ᵢ connected to the laser diode 1214 have the effect of increasing the amount of drive current drawn through the laser diode 1214, where the amplitude of the seed laser signal 1112 increases with an increased amount of drive current.

In the example of FIG. 12B, the seed drive signals 1122ᵢ take the form of digital seed drive signals 1122₁ through 1122ₙ, where each digital seed drive signal 1122ᵢ is a bit value that controls the state of its corresponding switch 12161 to govern whether its corresponding load 1218ᵢ is connected to the laser diode 1214. This may provide direct digital control over the pulse amplitude, shape, and width of the seed laser signal 1112 on a per clock cycle basis. Presuming that the seed laser circuitry 1102 is clocked at a rate that keeps up with the bit rate of the seed laser signal 1112 produced by the system controller 1006 (and that the switches 1216 are capable of switching at this rate), the seed laser circuitry 1102 may vary the pulse amplitude, shape, and width on a per clock cycle basis. Accordingly, the seed laser circuitry 1102 may support bit rates for the digital seed drive signal 1122 as well as a clock rate and switching rate for the seed laser circuitry 1102 while still directly controlling the pulse amplitude, shape, and width of the seed laser signal 1112 on a per clock cycle basis.

It will be appreciated that, by defining the values for the bits of the digital seed drive signals 1122₁ through 1122ₙ over time, the system controller 1006 may control which combinations of switches 1216ᵢ within the seed laser circuitry 1102 are enabled at a given time for their corresponding loads 1218ᵢ to draw current through the laser diode 1214. This in turn may control the amplitude, shape, and width of pulses produced by the laser diode 1214. In one example, pulse widths as short as approximately 100 picoseconds may be produced with a design approach such as that shown by FIG. 12B. It will be appreciated that any pulse widths may be produced with this and other design approaches. Moreover, it will be appreciated that users may choose to employ longer pulse widths depending on the circumstances. For example, some users may find pulse widths of approximately 1.5 to 1.7 nanoseconds desirable, or even longer pulse widths such as 5 nanoseconds.

In embodiments utilizing a single switching element, the laser diode 1214 may be biased using a regulated current source, with the switching element configured to modulate the regulated current supplied to the laser diode. The current-biased configuration may enable precise control of the laser diode 1214 operating current and temporal modulation of the emitted optical signal.

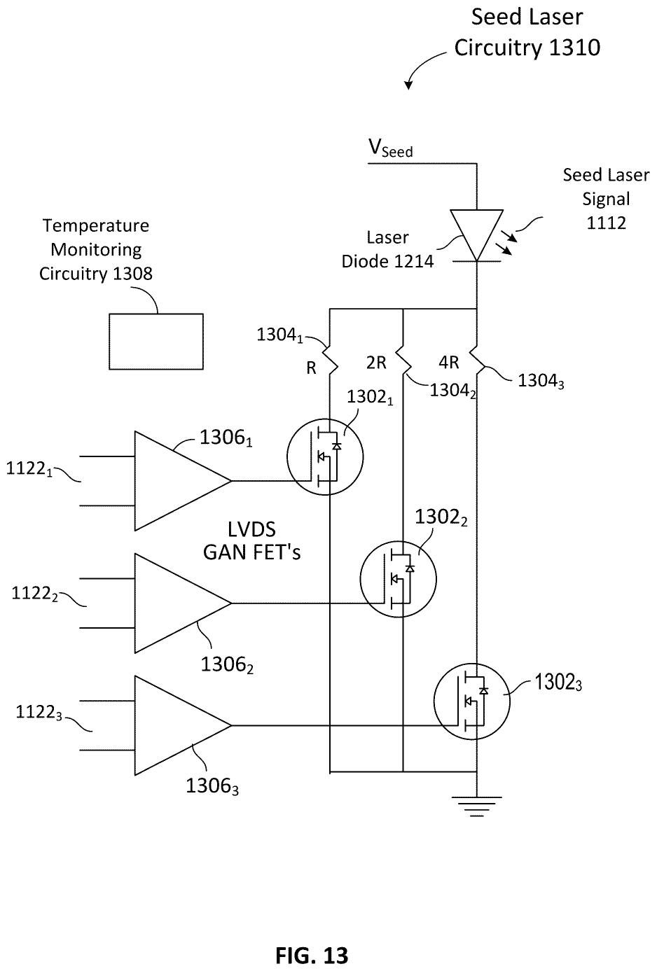

FIG. 13 shows another example seed laser circuitry 1310 that includes multiple branches, each with one field effective transistor 1302 and a resistor 1304. Similar to the pump laser circuitry 400 of FIG. 4A, the field effective transistor 1302 may be a GAN FET.

In this example, the resistors 1304₁, 1304₂, and 1304₃ exhibit resistances in relative ratios of R, 2R, and 4R, which results in the seed laser circuitry 1310 supporting seven discrete non-zero amplitude levels for the optical beam 212 depending on the values of the digital seed drive signals 1122₁, 1122₂, and 1122₃ as shown below:

| Seed | Seed | Seed | Resultant | |
|---|---|---|---|---|
| Drive | Drive | Drive | Approximated | Amplitude |
| Signal | Signal | Signal | Drive Current for | for Optical |
| 1122₁ | 1122₂ | 1122₃ | Laser Diode 1308 | beam 212 |
| 0 | 0 | 0 | Zero | Zero (no seed) |
| 0 | 0 | 1 | Vseed/4R | Level 1 Seed |
| 0 | 1 | 0 | Vseed/2R | Level 2 Seed |
| 0 | 1 | 1 | 3Vseed/4R | Level 3 Seed |
| 1 | 0 | 0 | Vseed/R | Level 4 Seed |
| 1 | 0 | 1 | 5Vseed/4R | Level 5 Seed |
| 1 | 1 | 0 | 3Vseed/2R | Level 6 Seed |
| 1 | 1 | 1 | 7Vseed/4R | Level 7 Seed |

The values Of V_{seed} and R may be empirically chosen by a user to achieve desired amplitudes for the seed laser signal 1112.

It will be appreciated that the combination of the timing and values of the seed drive signals 1122i may control the pulse width, pulse amplitude, and pulse shape for the seed laser signal 1112. In this example, a long period of non-zero seed drive signals yield a long pulse width, while a short period of non-zero seed drive signals 1122ᵢ yield a short pulse width. As another example, different pulse shapes may result from the rate of change in the amplitude for the seed laser signal over time. For example, continuing with the example from the table above, a sequence of digital inputs for 1122₁, 1122₂, and 1122₃ of (000), (111), (111), (111), (111), (111), (000) produce a sharply rising and sharply falling pulse; while the sequence of digital inputs for 1122₁, 1122₂, and 1122₃ of (000), (001), (100), (111), (100), (001), (000) produce a gently rising and gently falling pulse. Similarly, the sequence of digital inputs for 1122₁, 1122₂, and 1122₃ of (000), (111), (101), (011), (001), (000) produce a sharply rising and gently falling pulse; and the sequence of digital inputs for 1122₁, 1122₂, and 1122₃ of (000), (001), (011), (101), (111), (000) produce a gently rising and sharply falling pulse.

Moreover, as discussed herein, control may be exercised on a per clock cycle basis by varying the values of the seed drive signals 1122ᵢ over time to produce granular shot-to-shot control over the characteristics of the seed laser signal 1112. In some embodiments, the digital seed drive signals 1122₁, 1122₂, and 1122₃ may be provided to the seed laser circuitry 1102 as low voltage differential signaling (LVDS) inputs, in which case the seed laser circuitry 1302 may also include corresponding differential amplifiers 1306₁, 1306₂, and 1306₃ for each LVDS input 1122₁, 1122₂, and 1122₃ to control the states of transistor switches 1302₁, 1302₂, and 1302₃. The use of high speed GAN transistors as the switches in combination with an integrated LVDS interface for inputs may support short pulse widths. It will be appreciated that the digital seed drive signals 1122ᵢ need not be LVDS inputs. Moreover, while FIG. 4B shows GAN FETs being used as the switches 1302, it will be appreciated that other types of switches could be used—such as GaAs FETs, MOSFETs, etc.

Moreover, while FIG. 13 shows an example where three resistors are in parallel with relative resistance ratios of 1:2:4, there may be any number of additional parallel resistors in an effort to provide additional seed amplitude levels. To achieve a similar linear distribution of seed amplitude levels, when n parallel resistors 1304ᵢ are used, each resistor 1304ᵢ may exhibit a resistance value of 2ⁱ⁻¹R for all integer values of i in the range of (1, . . . , n). Further still, it will be appreciated that the loads 1304ᵢ may be formed from components other than (or in addition to) resistors, such as capacitors and/or inductors if desired by a user.

In some embodiments, a single-branch seed laser circuitry comprising a resistive element and a switching device in series with a laser diode. Such single-branch architecture may be particularly advantageous in applications where precise control of the laser drive current, high-speed modulation, and low-noise operation are desired. Typical use cases include optical systems requiring accurate pulse timing, compact module integration, or predictable optical output, such as seed lasers for amplification stages, time-of-flight measurement systems, optical communication transmitters, and other laser systems where simplified circuitry and direct current control are preferred. The single-branch configuration enables a streamlined design while maintaining the ability to generate consistent optical signals with minimal parasitic effects.

In one example, a multi-branch seed laser circuitry comprising a plurality of parallel branches, each including a resistive element and a switching device in series with a laser diode. The multi-branch architecture may be advantageous in applications requiring flexible control of the laser drive current, stepwise or composite pulse shaping, and scalable current handling. Typical use cases include laser systems where independent or coordinated modulation of multiple current paths is desired, such as programmable optical waveform generation, adaptive pulse amplitude control, high-power seed lasers, or optical systems requiring distributed thermal management and enhanced reliability. The multi-branch configuration enables modular design, precise shaping of optical pulses, and improved current distribution while maintaining the ability to generate high-fidelity optical signals for various laser applications.

In some embodiments, the selection between a single-branch and a multi-branch seed laser architecture may be based on system requirements, desired optical performance, and implementation considerations. A single-branch configuration may be preferred in applications emphasizing simplicity, compactness, high-speed pulse control, and low-noise operation, while a multi-branch configuration may be preferred in applications emphasizing flexible current modulation, pulse shaping, scalable current handling, and enhanced thermal or reliability management. The choice of architecture may be tailored to the specific needs of the laser system, enabling designers to balance design complexity, modulation capability, and operational performance in accordance with the requirements of the intended application.

FIG. 14A shows an example method 1400 for controlling the generation of pump laser signals according to some embodiments. At step 1402, the pump laser circuitry 1104 variably controls which laser diode among a plurality of redundant laser diodes is activated based on the pump drive signal(s) 1124. Step 1402 may be carried out by circuitry that variably controls which redundant laser diodes are activated as a function of the pump drive signal(s) 1124. For example, the variable control circuitry for step 1402 may comprise one or more switches whose switch states are controlled by the pump drive signal(s) 1124, and where the switch states control which of the redundant laser diodes is activated. However, it will be appreciated that other circuitry could be used for the variable control circuitry at step 1402.

At step 1404, the activated laser diode generates the pump laser signal 1114. Accordingly, it will be appreciated that by controlling the pump drive signals 224 over time, the pump laser circuitry 1104 may control the individual duty cycles of each laser diode among the redundant laser diodes while also controlling the overall duty cycle of pump laser signal 1114.

FIG. 14B shows an example pump laser circuitry 1104 for generating pump laser signals in response to pump drive signals in some embodiments. The pump laser circuitry 1104 includes a plurality of redundant laser diodes 1408ᵢ and a plurality of switches 1410ᵢ that control which of the redundant laser diodes 1408ᵢ is activated at a given time. Each laser diode 1408ᵢ may be any laser diode capable of producing laser pulses that exhibit the characteristics (e.g., wavelength and power characteristics) for the pump laser signals 1114.

By operating the individual laser diodes 1408ᵢ at duty cycles of less than 100%, the operational lifetime of each individual laser diode 1408ᵢ is expected to increase because its workload will be correspondingly reduced. Furthermore, through operations at sub-100% duty cycles, the operating temperature of each redundant laser diode 1408ᵢ may be reduced which may yield a further improvement in the heat characteristics of the laser source 102. Moreover, each laser diode 1408 may have a threshold amount of current that is needed in order for the laser diode 1408 to produce its pump laser signal 1114. Further still, the laser diodes 1408 may have a maximum current, and a user may find it desirable to operate the laser diodes 1408 at maximum current when activated in order to maximize efficiency. By switching between which of the laser diodes 1408 are activated, each laser diode 1408 may be operated at a reduced duty cycle (e.g., a 140% duty cycle or less) while running at maximum current, wherein the reduced duty cycle may have the effect of extending the laser diode's operational life relative to similar operation at higher duty cycles.

The number n of redundant laser diodes 1408ᵢ and switches 1410ᵢ may be any integer value greater than or equal to 2, where it will be appreciated that the upper limit for n can be any integer value to achieve a desired amount of redundancy for the pump laser circuitry 1304. In this regard, in some embodiments, n=2 (dual redundant laser diodes 1408₁ and 1408₂) is sufficient, although larger values for n may be utilized in this example if desired. In the example of FIG. 14B, each switch 1410i is connected in series with a corresponding laser diode 1408i as a switch-diode pair, and the different switch-diode pairs are arranged in parallel.

The pump drive signal 1124 may operate to control the state of switches 1410ᵢ to define which of the laser diodes 1408ᵢ is activated to draw current and produce the pump laser signal 1114. The redundant laser diodes 1408ᵢ may be coupled to a current source 1412 at its anode, either directly or indirectly (such as indirectly via their corresponding switches 1410ᵢ). The current source 1412 may draw from a voltage supply of Vₚᵤₘₚ (e.g., 14V). As noted herein, the current source 1412, in some embodiments, may be configured to provide current to the activated laser diode 1408 in an amount corresponding to the maximum desired operational current for the laser diode 1408 as per the specifications of the laser diode 1408.

In the example of FIG. 14B, the pump drive signals take the form of digital pump drive signals 1124₁ through 1124ₙ, where each digital pump drive signal 1124ᵢ is a bit value that controls the state of its corresponding switch 1410ᵢ to govern whether its corresponding laser diode 1408i is activated. In some embodiments, the switching rate of switches 1410 as caused by the digital pump drive signal 1124 may be much slower than the switching rate for the switch 1310 of the seed laser circuitry 1306 as discussed herein. For example, the switching rate of switches 1410 may be approximately 3 orders of magnitude slower than the switching rate of switch 1310. However, this need not be the case if a user desires faster switching for the pump laser circuitry 1304. In some embodiments, in operation, only one laser diode 1408ᵢ is activated at a given time to produce a desired pump laser signal 1114. Accordingly, in an example where there are two redundant laser diodes 1408₁ and 1408₂, the digital pump drive signals 1124₁ and 1124₂ may exhibit values of (00) for the use case where no pump laser signal 1114 is generated, (01) for the use case where laser diode 1408₁ is activated to generate the pump laser signal 1114, or (10) for the use case where laser diode 1408₂ is activated to generate the pump laser signal 1114. By controlling the sequence of bit values for pump drive signals 1124₁ through 1124ₙ, a user may control the pump power of the pump laser signal 1114 by adjusting the duty cycle of the pump drive signals 1124₁ through 1124ₙ. Normally, in an example where there are two redundant laser diodes 1408₁ and 1408₂, it is expected that each laser diode 1408₁ and 1408₂ would be operated at a duty cycle not greater than 140%. To reduce the pump energy, while maintaining the same pump drive efficiency, duty cycles below 140% may be employed for the dual redundant laser diodes 1408₁ and 1408₂. For example, individual duty cycles as low as 14% may be employed, which may yield an overall duty cycle for the pump laser signal 1114 of 10%. It will be appreciated that other values for duty cycles could be employed.

In the event one of the dual redundant laser diodes 1408₁ and 1408₂ fails, the surviving laser diode may be operated at a higher duty cycle (e.g., 100%) to compensate for the failure until a repair or replacement may be made. Furthermore, it will be appreciated that operating an individual laser diode 1408₁ or 1408₂ continuously at a 100% duty cycle may allow for the detection of a failure in that individual laser diode 1408₁ or 1408₂.

In the illustrated embodiment of FIG. 14B, the laser diode is top-side or high-side driven, meaning that the control device, or switch 1410 is coupled between the power supply and the laser diode 1408. In other words, the switches 1410 controls how much current flows into the laser diode 1408 and a bottom terminal of the laser diode 1408 is coupled to a reference potential or ground. The top-side topology enables controlling sourcing of current into the pump laser diode, facilitating precise current regulation and reduces coupling of switching transients into the reference potential, thereby supporting stable and reliable operation of the pump laser.

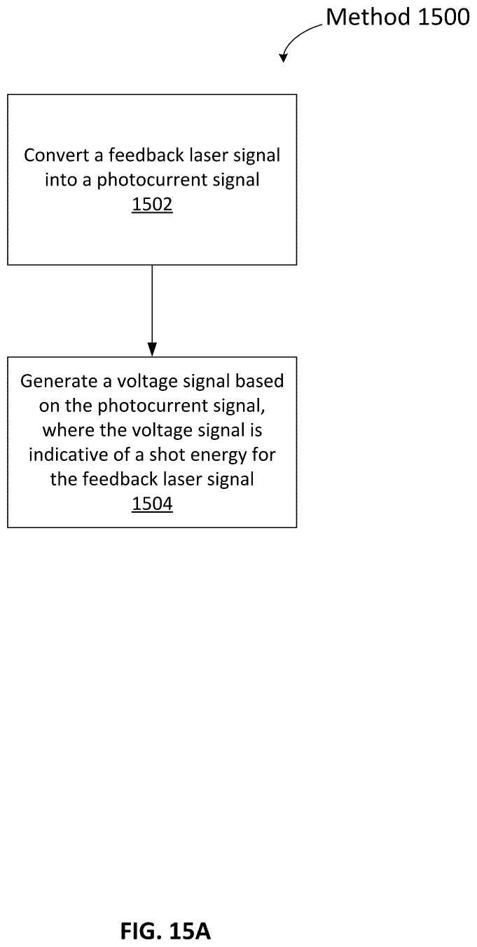

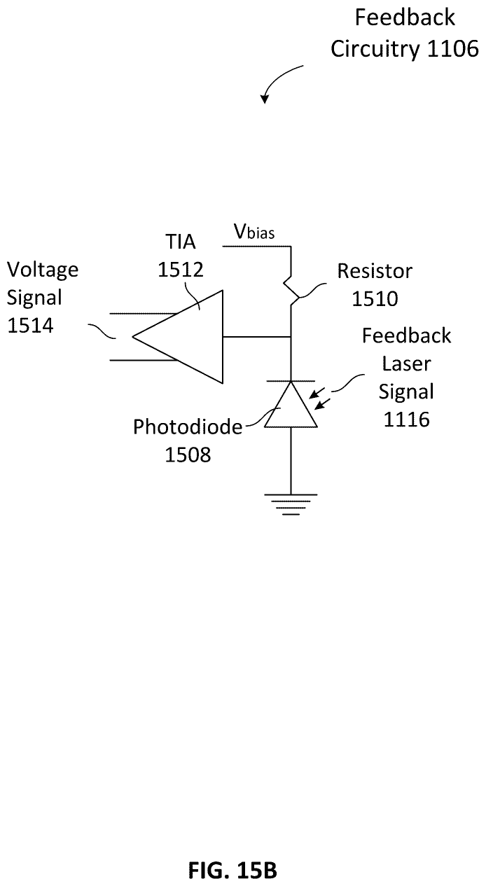

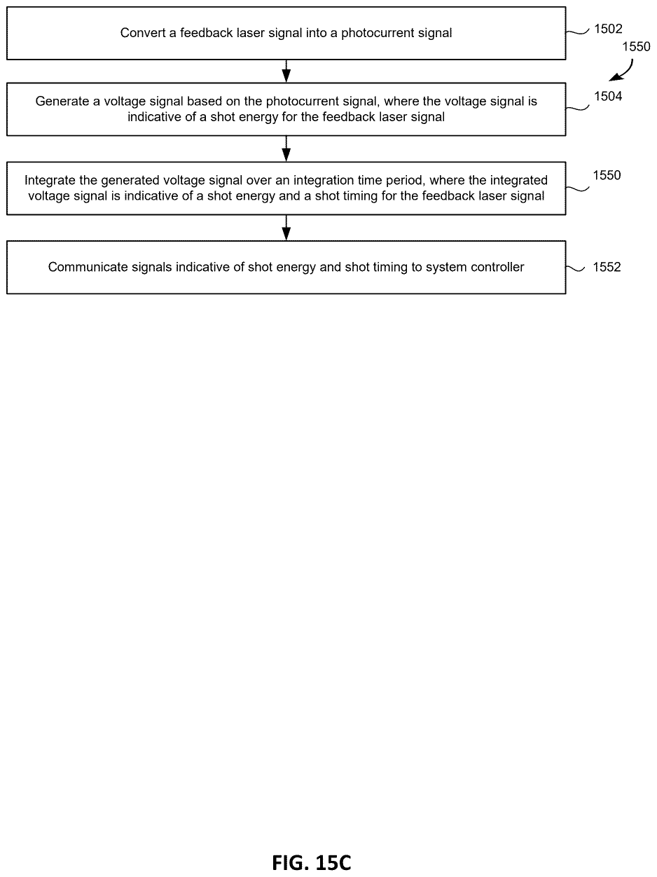

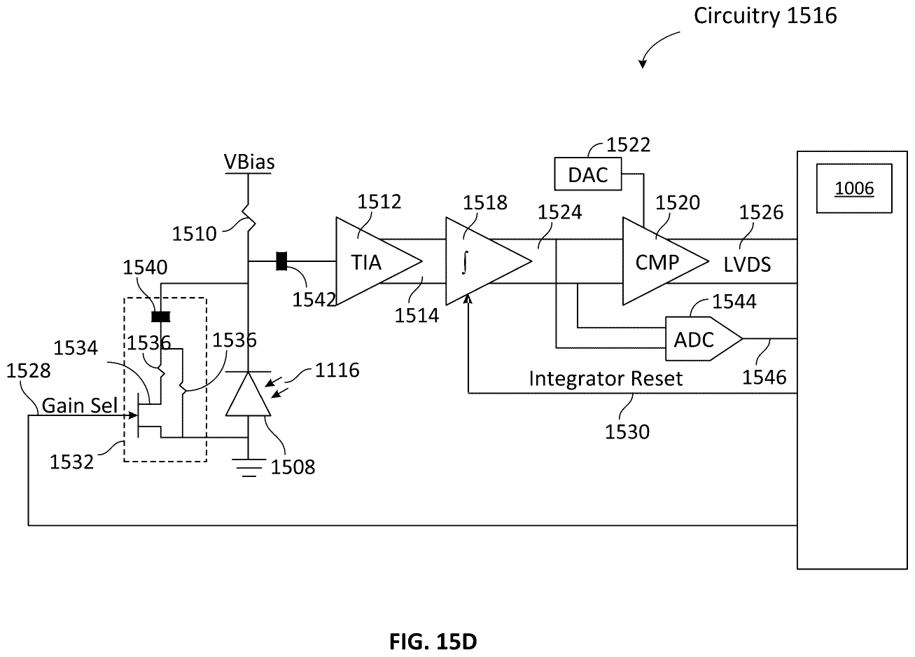

FIG. 15A shows an example method 1500 to be carried out by the feedback circuitry 1106 in some embodiments. At step 1502, the feedback circuitry 1106 converts a feedback laser signal 1116 into a photocurrent signal. As an example, this may be accomplished by tapping into the amplified laser signal 1020 and feeding light from the amplified laser signal 1020 back to the feedback circuitry 1106 via optical fiber 1016 as the feedback laser signal 1116. The feedback circuitry 1106 may include a photodiode that receives the feedback laser signal 1116 and generates the photocurrent in response to the received feedback laser signal 1116. At step 1504, the feedback circuitry generates a voltage signal based on the photocurrent signal, where this voltage signal is indicative of a shot energy for the feedback laser signal. Information may then be derived from this voltage signal regarding whether the shot energy indicated by the feedback laser signal matches an expected shot energy for the amplified laser signal 1020. The system controller 1006 may use this information to finetune the seed drive signals 1122ᵢ and pump drive signals 1124ᵢ in order to achieve amplified laser signals 1020 of desired shot energies.

FIG. 15B shows an example feedback circuitry 1106 in some embodiments. The feedback circuitry 1106 shown by FIG. 15B includes an optical input from the optical amplifier 1004 in the form of the feedback laser signal 1016. The feedback circuitry 1106 may also include an electronic output to the system controller 1006 to provide the system controller 1006 with information about one or more characteristics of the feedback laser signal 1116 such as shot energy.

Feedback circuitry 1106 of FIG. 15B includes a photodiode 1508 that receives the feedback laser signal 1116. The photodiode 1508 may be connected to ground through its anode and may be biased to generate photocurrent in response to incident light via a bias voltage (V_{bias}) and resistor 1510 connected in series to its cathode. Circuitry within the feedback circuitry 1106 may then convert this photocurrent into a voltage signal 1514, where voltage signal 1514 may indicate the amplitude or energy of the feedback laser signal 1116 from which the photocurrent was generated. In some embodiments, this conversion circuitry may comprise a transimpedance amplifier (TIA) 1512 that taps into the photocurrent generated by the photodiode 1508 and converts the tapped current into the voltage signal 1514. In one example, the feedback laser signal 1116 may be representative of the amplified laser signal 1020, the voltage signal 1514 may indicate a power or shot energy for the amplified laser signal 1020. Although not depicted in FIG. 15B, the feedback circuitry 1106 may include an integration capacitor and a reset capacitor similar to capacitors 1542 and 1540 of FIG. 15D. The integration capacitor may convert current pulse from a light detector into a voltage level that represents a total energy of a laser pulse. The integration capacitor may hold the integrated charge, allowing the laser system to digital the pulse energy. The reset capacitor may clamp the integrator circuit to force an operational amplifier to ground. More details regarding the integration capacitor and reset capacitor is discussed in relation to FIG. 15D.

In some embodiments, calibration may be employed to ascertain the relationship scaling between the amplified laser signal 1020, the feedback laser signal 1116, and the voltage signal 1514. While FIG. 15B shows an example where the conversion circuitry takes the form of TIA 1512, it will be appreciated that circuitry other than TIAs could be employed to convert the photocurrent through photodiode 1508 into the voltage signal 1514. For example, the conversion circuitry may comprise circuitry that measures the voltage drop across resistor 1510, where this voltage drop may be indicative of the photocurrent drawn by the photodiode 1508 in response to the incident feedback laser signal 1116.

The voltage signal 1514 may be used by the system controller 1006 to determine laser failures in the laser system 1000, where a laser failure is deemed to occur where the shot energy/power is lower than expected. Moreover, the voltage signal 1514 may also indicate when an unintended (or “rogue”) laser pulse has been generated by the laser system 1000. As such, the system controller 1006 may use the voltage signal 1514 to detect rogue laser pulse shots for safety purposes.

FIG. 15C shows an example process flow for generating information indicative of a shot energy and shot timing for the amplified laser signal 1020 based on the feedback laser signal 1116 in some embodiments. Steps 1552 and 1554 of FIG. 15C may operate as described herein for FIG. 15A. At step 1550, the feedback circuitry 1106 integrates the voltage signal 1514 over an integration time period to produce an integrated voltage signal. This integrated voltage signal indicates both shot energy and a shot timing for the feedback laser signal 1116 (and by extension the amplified laser signal 1020). At step 1552, the feedback circuitry 1106 communicates signals indicative of shot energy and shot timing for the feedback laser signal 1116 to the system controller 1006.

FIG. 15D shows another example feedback circuitry 1516 for carrying out the process flow of FIG. 15C in some embodiments. The feedback circuitry 1516 may translate feedback light from a laser pulse into voltage signals indicative of a shot energy according to some embodiments. In this example, the feedback circuitry 1516 also includes an integrator 1518 that operates to integrate the voltage signal 1514 over an integration time period that is defined by the system controller 106 via an integrator reset control signal 1530. The integrator 1518 may produce an integrated voltage signal 1524. As shown by FIG. 15D, the integrator 1518 may be connected to the output of the transimpedance amplifier 1512.

The integrated voltage signal 1524 may also indicate the shot energy for the feedback laser signal 1116. As such, the integrated voltage signal 1524 may be output to the system controller 106 via an analog-to-digital converter (ADC) 1544, where the ADC 1546 may be resident in the feedback circuitry 1106 or the system controller 1006.

The integrated voltage signal 1524 may also be fed to a comparator 1520 to produce a signal 1526 indicative of shot timing for the feedback laser signal 1116. As shown by the example of FIG. 15D, the comparator 1520 may be coupled to the output of the integrator 1518. The comparator may compare the integrated voltage signal 1524 with a threshold voltage defined by a digital-to-analog converter (DAC) register 1534. In some embodiments, the value stored in the DAC register 1522 may be defined by the system controller 1006 and used as a threshold for detecting the presence of light pulses on a shot-by-shot basis for the system. This shot-by-shot control means that the system controller 1006 may change the threshold value stored in the DAC register 1522 as a function of the expected shot energy of each pulse fired by the system.

The comparator output 1526 may indicate not only shot timing but also the existence of an unexpected shot. The comparator output 1526 may take the form of an LVDS signal provided to the system controller 1006.

The feedback circuitry 1516 may also include gain selection circuitry 1532, which defines a dynamic range for the photocurrent signal produced by the photodiode 1508 in response to the feedback laser signals 216. The gain selection circuitry 1532 may define this dynamic range based on a gain select control signal 1528 from the system controller 1006. Given that there may be a wide variation of energy in the feedback laser signal 1116, it may be desirable to control the dynamic range of the photocurrent that will be passed to transimpedance amplifier 1512 so that the expected minimum and maximum currents for the transimpedance amplifier 1512 (and thus the expected minimum and maximum voltages for voltage signal 1514) stay within the operational bounds of the ADC 1544.

In various embodiments, the gain selection circuitry 1532 may be connected across the cathode and anode of the photodiode 1508 in FIG. 15D, and the gain selection circuitry 1532 may comprise a switch 1534 (e.g., a transistor) that controls how much resistance is connected across the photodiode 1508 (see resistors 1536). Accordingly, the gain selection circuitry 1532 may act as an AC-coupled resistive shunt that helps provide high speed, low capacitance switching.

In this example, if the switch 1534 is closed by the gain select control signal 1528, then both resistors 1536 may be connected in parallel across the photodiode 1508. If the switch 1534 is opened in this example by the gain selection control signal 1528, then only one of the resistors is connected across the photodiode 1508. Accordingly, the state of switch 1534 may control the gain of the photodiode 1508 with respect to the photocurrent signal it produces in response to the feedback laser signal 1116. In this fashion, the dynamic range of currents entering the transimpedance amplifier 1512 may be tuned via the gain selection control signal 1528. For example, if the feedback laser signal 1116 is expected to have a relatively large shot power, the system controller 1006 may assert the gain select control signal 1528 in order to attenuate the amplitude of the current read by the transimpedance amplifier. In contrast, if the feedback laser signal 1116 is expected to have a relatively small shot power, the system controller 106 may de-assert the gain select control signal 1528 in order to avoid the attenuation of the amplitude of the current read by the transimpedance amplifier that would be caused if both resistors 1536 were connected to draw current. In this fashion, the system controller 106 may establish ranges of shot powers for the amplified laser signal 1020 that would qualify as “high” shot powers and “low” shot powers, and then control the gain control signal 1528 accordingly in order to tune the feedback circuitry 1516 appropriately. It should also be understood that the system controller 1006 may utilize knowledge of the gain attenuation controlled via the gain select control signal 1528 to translate the digitization of the integrated voltage signal 1524 into a value that represents the measured shot energy as detected by the feedback circuitry 1516.

Capacitors 1540 and 1542 may serve to provide AC coupling for the feedback circuitry 1516.

In some embodiments, in operation, the system controller 1006 may reset the integration time period of the integrator 1518 via the integration reset control signal 1530 before and after a laser pulse shot occurs and the integrated voltage signal 1524 is read. In one example, the timing sequence may operate as follows: (1) determine the high/low power status of the amplified laser signal 1020, (2) set the gain select control 1528 signal based on the determined high/low power status, (3) reset the integration time period of the integrator 1518 via the integrator reset control signal 1530, (4) fire the amplified laser signal 1020, (5) read the integrated voltage signal value 1524, and (6) reset the integration time period of the integrator 1518 via the integrator reset control signal.

The comparator signal return exhibited by voltage signal 1526 may be asynchronous to the fire signal for the laser system 1000, which limits fire timing feedback synchronization to +/−½ of the fire timing clock for the laser system 1000. Moreover, the integrator 1518 may have a repeatable and known slope covering the entire shot pulse 220. Using a test setup with a target at a precisely known target distance, the set point of comparator 1520 may be defined through calibration so that the output of comparator 1520 aligns with the fire clock to improve the precision of the level timing. The shot energy may also affect the timing, so a timing correction may also be employed as part of calibration to further improve the timing precision.

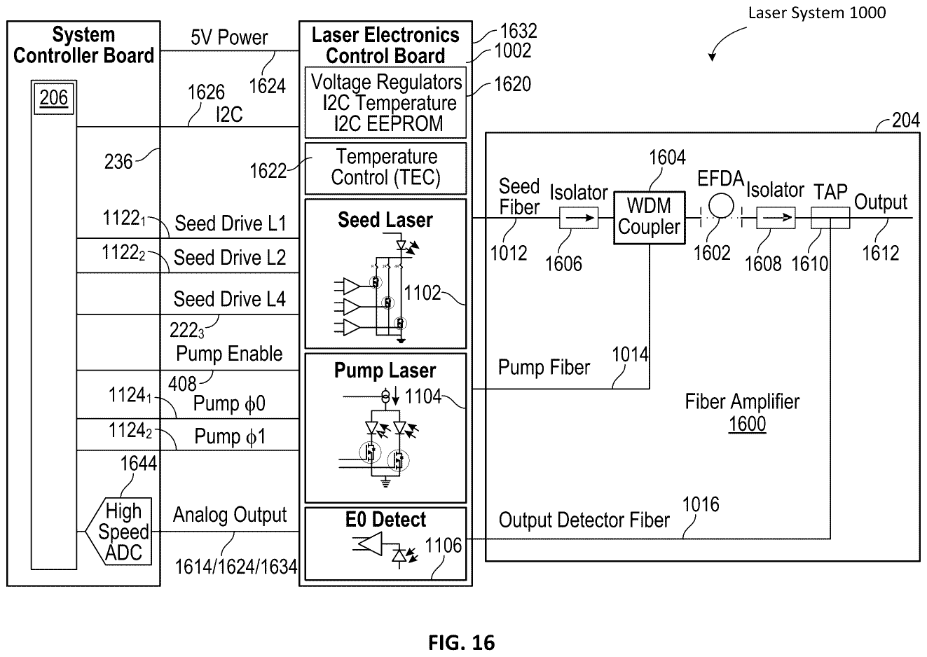

FIG. 16 shows a detailed view of a laser system 1000 in accordance with an example embodiment. With this example, the optical amplifier 1004 may take the form of a fiber amplifier 1600. The fiber amplifier 1600 may include a doped fiber amplifier such as an Erbium-doped fiber amplifier (EFDA) 1602. An optical isolator 1606 may be coupled to optical fiber 1012 for receiving the seed laser signal 1112, and an optical coupler 1604 (such as a wavelength division multiplexing (WDM) coupler) may couple the seed laser signal 1112 received via optical fiber 1012 with the pump laser signal 1114 received via optical fiber 1014. The coupled seed and pump laser signals 1112 and 1114 may then be amplified within the EFDA 1602.

The amplified optical output of the EFDA 1602 may be passed through optical isolator 1608. In example embodiments where the laser controller 1002 includes feedback circuitry 1106, the fiber amplifier 900 may also include an optical tap 1610 that taps into the amplified optical output of the EFDA 1602 passed by the optical isolator 1608 to provide the feedback laser signal 1116 to the laser controller via optical fiber 1016. The amplified optical output passed as output 1612 from the fiber amplifier may serve as the amplified laser signal 1020 which is transmitted by the laser system 1000.

As discussed above, the laser electronics control board 1632 may include the circuitry of the laser controller 1002, including the seed laser circuitry 1102, the pump laser circuitry 1104, and the feedback circuitry 1106.

The laser controller 1002 may include additional components. For example, the laser controller 1002 may include temperature control circuitry 1622 to monitor temperatures on the laser electronics control board 1632. The laser controller 1002 may also include voltage regulators and an EEPROM and remote temperature monitoring circuitry 1620 that interfaces with the system controller 1006 via an I2C bus 1626. The EEPROM may provide identifying information such as board identification, manufacture date, lot, rev, P/N, and the like. In some embodiments, voltage rails needed by components on the laser electronics control board 1632 are generated on the board 1632 by voltage regulators from a 5V power input 1624. Furthermore, the laser controller 1002 may include one or more LEDs that indicate operational status information such as indications of main power, pump power, seed activity, and the like.

The laser controller 1002 may receive digital inputs from the system controller 1006 such as the seed drive signals 1122₁, 1122₂, the pump enable signal 408, and the pump drive signals 1124₁, 1124₂ as discussed herein. Furthermore, the laser controller 1002 may provide an analog electronic output to the system controller 1006 in the form of voltage signals 1614, 1624, and/or 1634. As shown by the example of FIG. 16, the system controller 1006 may include a high speed ADC 1644 for converting the analog output(s) 1614, 1624, and/or 1626 into digital data. Laser control functions such as pulse repetition rate checking, temperature monitoring, and lower power monitoring may be implemented by the logic carried out by the system controller 1006.

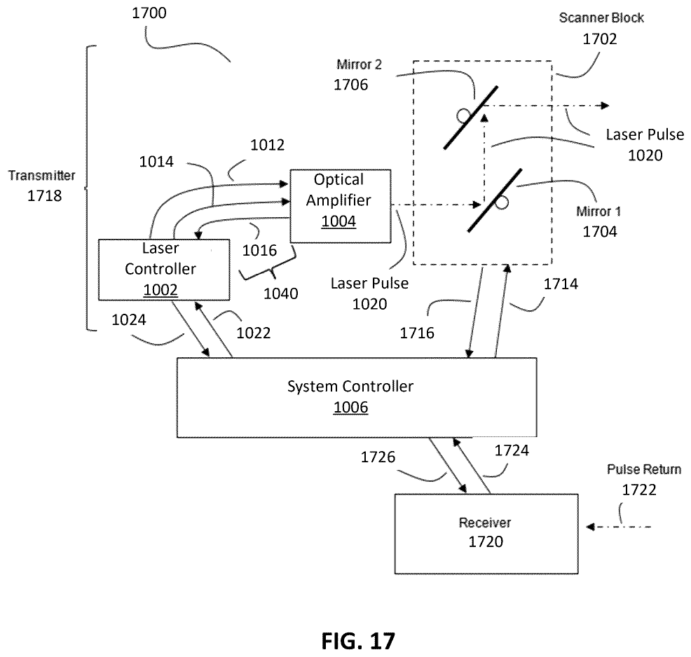

In another example embodiment, the example laser systems 1000 described herein may be deployed in larger systems such as a LiDAR system 1700 as shown by FIG. 17. As shown by the example of FIG. 17, the LiDAR system 1700 includes a LiDAR transmitter 1718 and a LiDAR receiver 1720. The laser controller 1002 and optical amplifier 1004 may be deployed as part of the LiDAR transmitter 1718 to serve as the laser source that generates the laser pulses 1020 that serve as LiDAR pulse shots. The laser pulses 1020 output by the optical amplifier 1004 may be directed toward a target in the environment by mirrors 1704 and 1706 within a scanner block 1702 (or mirror subsystem) of the LiDAR transmitter 1718.

The system controller 1006 may control not only the operations of the laser controller 1002, but also the operations of the scanner block 1702 (via mirror control signals 1714 that control the scanning of mirrors 1704 and 1706) as well as the operations of the LiDAR receiver 1720 (via receiver control signals 1724 that may control a variety of aspects of receiver operations). In this fashion, the system controller 1006 may act as a system control circuit for the LiDAR system 1700. For example, the system controller 1006 may drive mirror 1704 to scan in a resonant mode across azimuths while step scanning mirror 1706 across elevations, where this scanning is governed by a shot list of range points in the environment to be targeted with the laser pulses 1020. The shot list may not only define the order of targeting locations for the laser pulses. In one example, the shot list may also define additional characteristics of each laser pulse, including but not limited to a shot energy (pulse amplitude), pulse width, pulse shape, and/or shot time for each laser pulse. Moreover, the pulse amplitude, pulse width, and pulse shape may be defined on a per clock cycle basis for each shot. Feedback signals 1716 from the scanner block may be monitored by the system controller 1006 to measure the mirror scan positions for feedback control of the mirror control signals 1714 to achieve desired mirror scan positions over time.

The LiDAR receiver 1720 includes a photodetector array that receives incident light including pulse returns 1722 from the laser pulses 1020 fired by the LiDAR transmitter 1718. Signal processing circuitry within the LiDAR receiver 1720 may detect the pulse returns 1722 to support the computation of range point measurements 1724 for the range points that were targeted by the laser pulses 1020. A LiDAR point cloud may then be populated by these range point measurements and other information derived from the pulse returns 1722 to maintain a 3D map of the LiDAR system's field of view. System controller 1006 may provide control signals 1726 to the LiDAR receiver to control the operations of the LiDAR receiver 1720, such as control signals that indicate which photodetectors of its photodetector array should be used for detecting pulse returns 1022 over time and define the timing windows for such detections.

By using the laser systems 1000 described herein as the controlled laser source for the LiDAR system 1700, a user is provided with significant improvements in configuring the LiDAR system with a desirable footprint for its transmitter 1718. Because the laser controller 1002 may be separated from the optical amplifier 1004 via physical separation 1040 provided via the optical coupling 1010 (e.g., optical fibers 1012, 1014, and 1016), the size of transmission area of the LiDAR transmitter 1718 need not also accommodate the footprint of the laser controller 1002 because the laser controller 1002 may be positioned elsewhere. This may be particularly advantageous in embodiments where the LiDAR system 1700 is deployed on a vehicle (e.g., an automobile). For example, the optical amplifier 1004 and scanner block 1702 may be deployed as part of a rear view mirror assembly of a vehicle, and the laser controller 1002 may be positioned elsewhere in the vehicle. In some examples, the laser controller 1002 is positioned under the dashboard of the vehicle, in a center console of the vehicle, in the trunk of the vehicle, or in some other portion of the vehicle (e.g., a climate-controlled area of the vehicle). This arrangement may provide for a more compact set of components to be included in a relatively small enclosure such as the rear view mirror assembly. In some embodiments, optical fibers (e.g., 1012, 1014, 1016) may be run from the laser controller 1002 positioned elsewhere in the vehicle to the optical amplifier 1004 in the rear view mirror assembly so that the optical amplifier 1004 may produce the laser pulses 1020 that are directed toward targets by the scanner block 1702.

Further still, the LiDAR system 1700 may exhibit improved heat distribution characteristics because the laser controller 1002 may be positioned in a cooler location—which may be a climate-controlled location—in order to reduce the risk of overheating. This may also be particularly advantageous in embodiments where the LiDAR system 1700 is used in potentially hot environments such as deployments on vehicles (e.g., automobiles). For example, the laser controller 1002 may be positioned in a climate-controlled compartment of the vehicle, while the optical amplifier 1004 and scanner block 1702 may be positioned in locations of the vehicle that may be subject to larger temperature swings and/or higher temperatures.

While an example use with vehicles is described herein, it will be appreciated that a LiDAR system 1700 which incorporates the laser system 1000 may be deployed for use cases other than vehicles such as mining applications, forestry applications, aerial applications (e.g., aerial mapping, aerial surveillance, self-guided munitions, etc.), satellite applications, and/or the like. Moreover, it should also be understood that the vehicle use cases need not be limited to automobile use cases. In some examples, the vehicles with which the LiDAR system 1700 and laser system 1000 could be used include trains, aerial vehicles, spacecraft, etc.

While example embodiments have been described, various modifications may be made thereto that still fall within the scope described herein. For example, while FIG. 16 shows an example of the feedback circuitry 1106 where a photodiode is located on the laser electronics control board 1632, it will be appreciated that the photodiode may be a part of the optical amplifier 204 or the fiber amplifier 1600. With such an arrangement, the laser controller 1002 may include the photodiode that is located on the optical amplifier 1004 or fiber amplifier 1600, and the optical fiber 1016 that connects the optical amplifier 1004 with the feedback circuitry 1106 of the laser controller 1002 could be replaced with a wire, cable, or the like that provides an electrical interface through which an electrical signal corresponding to a photocurrent generated by the photodiode is communicated. These and other modifications will be recognizable upon review of the teachings herein.

While particular elements, embodiments and applications have been shown and described, it will be understood, of course, that the claims are not limited thereto since modifications may be made by those skilled in the art without departing from the spirit and scope of the present disclosure, particularly in light of the foregoing teachings. Such modifications are to be considered within the purview and scope of the claims appended hereto.

While specific examples are described above for illustrative purposes, various equivalent modifications are possible. For example, while processes or blocks are presented in a given order, alternative implementations may perform routines having steps, or employ systems having blocks, in a different order, and some processes or blocks may be deleted, moved, added, subdivided, combined, or modified to provide alternative or sub-combinations. Each of these processes or blocks may be implemented in a variety of different ways. Also, while processes or blocks are at times shown as being performed in series, these processes or blocks may instead be performed or implemented concurrently or in parallel or may be performed at different times. Further any specific numbers noted herein are only examples: alternative implementations may employ differing values or ranges.

Throughout this specification, plural instances may implement components, operations, or structures described as a single instance. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein. Furthermore, any specific numbers noted herein are only examples: alternative implementations may employ differing values or ranges.

Components may be described or illustrated as contained within or connected with other components. Such descriptions or illustrations are only examples, and other configurations may achieve the same or similar functionality. Components may be described or illustrated as “coupled,” “couplable,” “operably coupled,” “communicably coupled” and the like to other components. Such description or illustration should be understood as indicating that such components may cooperate or interact with each other, and may be in direct or indirect physical, electrical, or communicative contact with each other.

Components may be described or illustrated as “configured to,” “adapted to,” “operative to,” “configurable to,” “adaptable to,” “operable to” and the like. Such description or illustration should be understood to encompass components both in an active state and in an inactive or standby state unless required otherwise by context.

The use of “or” in this disclosure is not intended to be understood as an exclusive “or.” Rather, “or” is to be understood as including “and/or.” For example, the phrase “providing products or services” is intended to be understood as having several meanings: “providing products,” “providing services,” and “providing products and services.”

Headings in this application may be provided for organization and may not necessarily be used to interpret or constrain the purview and scope of the claims appended hereto. Moreover, concepts or features of technologies described under a particular heading may be used in technologies described under other headings. Accordingly, technologies described under a particular heading are not limited to the concepts or features described under that particular heading.

It may be apparent that various modifications may be made, and other embodiments may be used without departing from the broader scope of the discussion herein. Therefore, these and other variations upon the example embodiments are intended to be covered by the disclosure herein.

1. A system comprising:
a laser source including:
a pump laser including:
multiple first laser diodes configured to generate optical energy;
a current source coupled to the multiple first laser diodes; and
multiple first switches, a first switch of the multiple first switches coupled in series with a first laser diode of the multiple first laser diodes, wherein the first switch is configured to receive a pump drive signal of multiple pump drive signals and control activation of a corresponding first laser diode based on the pump drive signal;
a seed laser including;
a second laser diode configured to generate an optical beam; and
a second switch configured to receive a seed drive signal and to control current flow through the second laser diode based on the seed drive signal to control a pulse amplitude of the optical beam; and
an optical amplifier configured to receive the optical beam and the optical energy and to generate a laser pulse based on the optical beam and the optical energy; and
a system controller configured to generate the pump drive signal and the seed drive signal.

2. The system of claim, wherein the laser source further includes feedback circuitry, the feedback circuitry including:
a photodiode configured to receive energy from the laser pulse and output current; and
conversion circuitry configured to convert the current into a voltage signal;
wherein the system controller is further configured to determine an energy of the laser pulse based on the voltage signal.

3. The system of claim, wherein the conversion circuitry includes:
a capacitor configured to charge based on the current; and
an amplifier configured to read a value of a voltage of the capacitor and output the voltage signal.

4. The system of claim, wherein the feedback circuitry further includes gain selection circuitry configured to define a dynamic range for the current based on a gain select control signal.

5. The system of claim, further comprising:
a scanner block configured to transmit the laser pulse; and
a receiver configured to receive a returned laser pulse.

6. The system of claim wherein the current source includes a constant current source.

7. The system of claim wherein the multiple first laser diodes include only two first laser diodes, and wherein the system controller is configured to generate two pump drive signals to operate the two first laser diodes at duty cycles of less than 100%.

8. The system of claim wherein the first switch of the multiple first switches is coupled between the first laser diode of the multiple first laser diodes and the current source.

9. The system of claim wherein the first switch of the multiple first switches is coupled between the first laser diode of the multiple first laser diodes and a reference potential.

10. The system of claim wherein the pump laser further includes multiple resistive elements, a first resistive element of the multiple resistive elements coupled between the first switch of the multiple first switches and the reference potential.

11. A system comprising:
a pump laser including:
multiple first laser diodes configured to generate optical energy;
a current source coupled to the multiple first laser diodes; and
multiple first switches, a first switch of the multiple first switches coupled in series with a first laser diode of the multiple first laser diodes, wherein the first switch is configured to receive a pump drive signal of multiple pump drive signals and control activation of a corresponding first laser diode based on the pump drive signal;
a seed laser including;
a second laser diode configured to generate an optical beam; and
a second switch configured to receive a seed drive signal and to control current flow through the second laser diode based on the seed drive signal to control a pulse amplitude of the optical beam; and
an optical amplifier configured to receive the optical beam and the optical energy and to generate a laser pulse based on the optical beam and the optical energy.

12. The system of claim, further comprising feedback circuitry, the feedback circuitry including:
a photodiode configured to receive energy from the laser pulse and output current; and
conversion circuitry configured to convert the current into a voltage signal usable to determine an energy of the laser pulse.

13. The system of claim, wherein the conversion circuitry includes:
a capacitor configured to charge based on the current; and
an amplifier configured to read a value of a voltage of the capacitor and output the voltage signal.

14. The system of claim, wherein the feedback circuitry further includes gain selection circuitry configured to define a dynamic range for the current based on a gain select control signal.

15. The system of claim, wherein the current source includes a constant current source.

16. The system of claim, wherein the multiple first laser diodes include only two first laser diodes configured to operate at duty cycles of less than 100%.

17. The system of claim, wherein the first switch of the multiple first switches is coupled between the first laser diode of the multiple first laser diodes and the current source.

18. The system of claim wherein the first switch of the multiple first switches is coupled between the first laser diode of the multiple first laser diodes and a reference potential.

19. The system of claim, wherein the pump laser further includes multiple resistive elements, a first resistive element of the multiple resistive elements coupled between the first switch of the multiple first switches and the reference potential.

20. A method comprising:
receiving, at a pump laser circuitry that includes multiple first laser diodes, a current source, and multiple first switches, multiple pump drive signals;
controlling, utilizing the multiple first switches and based on the multiple pump drive signals, activation of one or more first laser diodes of the multiple first laser diodes;
generating, utilizing the one or more first laser diodes, optical energy;
receiving, at a seed laser circuitry that includes a second laser diode and a second switch, a seed drive signal;
based on the seed drive signal, utilizing the second switch to control current flow through the second laser diode;
generate, utilizing the second laser diode, an optical beam, wherein a pulse amplitude of the optical beam is determined by the current flow through the second laser diode; and
generate, based on the optical beam and the optical energy, a laser pulse.

21.-180. (canceled)
